(19) United States
(12) Patent Application Publication
(10) Pub. No.: US 2026/0143956 A1
(43) Pub. Date: May 21, 2026

(54) OPTICAL DEVICE, DISPLAY DEVICE INCLUDING OPTICAL DEVICE, AND ELECTRONIC DEVICE INCLUDING DISPLAY DEVICE

(71) Applicant: Samsung Display Co., Ltd., Yongin-si (KR)

(72) Inventors: Hae Ju YUN, Yongin-si (KR); Soo Bin KIM, Yongin-si (KR); Yong Seok KIM, Yongin-si (KR); Ji Young NAM, Yongin-si (KR); Dong Chul SHIN, Yongin-si (KR); Jong Cheon LEE, Yongin-si (KR)

(21) Appl. No.: 19/258,119

(22) Filed: Jul. 2, 2025

(30) Foreign Application Priority Data
Nov. 18, 2024 (KR) 10-2024-0163768

(51) Int. Cl. H10K 59/80; G02B 1/00

(52) U.S. Cl. CPC H10K 59/879; G02B 1/002

(57) ABSTRACT

Provided are an optical device, a display device including the optical device, and an electronic device including the display device. According to one or more embodiments of the present disclosure, there is provided an optical device including a substrate, a first metalens layer disposed on a surface of the substrate and including a plurality of first nanostructures, and a second metalens layer disposed on the surface of the substrate, overlapping with the first metalens layer in a thickness direction of the substrate, and including a plurality of second nanostructures. The first metalens layer may include a first refractive portion where the plurality of first nanostructures is disposed to refract incident light, and a first non-refractive portion where the plurality of first nanostructures is not disposed. The plurality of second nanostructures may overlap with the first refractive portion and the first non-refractive portion in the thickness direction of the substrate.

### CROSS-REFERENCE TO RELATED APPLICATION

This application claims priority to and the benefit of Korean Patent Application No. 10-2024-0163768 filed on Nov. 18, 2024 in the Korean Intellectual Property Office, the disclosure of which is incorporated herein by reference in its entirety.

### BACKGROUND

### 1. Field of the Disclosure

The present disclosure relates to an optical device, a display device including the optical device, and an electronic device including the display device.

### 2. Description of the Related Art

As the information society evolves, various display devices have been developed to display information. For example, an augmented reality (AR) device is a display device that superimposes a virtual image on a real-world image seen by the user's eyes. For another example, a 3D image display device separately displays a left-eye image and a right-eye image in order to give a viewer 3D experiences using binocular parallax.

For an augmented reality device or a stereoscopic image display device, it is important to implement it so that light output from the display device is focused exactly on the user's eyes. To this end, research is ongoing on an optical device that adjusts light paths to focus on an accurate location by addressing spherical aberration occurring in a lens.

### SUMMARY

Aspects of the present disclosure provide an optical device that adjusts light paths to focus on an accurate location by addressing spherical aberration.

Aspects of the present disclosure also provide a display device including an optical device that adjusts light paths to focus on an accurate location by addressing spherical aberration.

Aspects of the present disclosure also provide an electronic device including a display device that adjusts light paths to focus on an accurate location by addressing spherical aberration.

According to one or more embodiments of the present disclosure, there is provided an optical device including a substrate, a first metalens layer disposed on a surface of the substrate and including a plurality of first nanostructures, and a second metalens layer disposed on the surface of the substrate, overlapping with the first metalens layer in a thickness direction of the substrate, and including a plurality of second nanostructures. The first metalens layer may include a first refractive portion where the plurality of first nanostructures is disposed to refract incident light, and a first non-refractive portion where the plurality of first nanostructures is not disposed. The plurality of second nanostructures may overlap with the first refractive portion and the first non-refractive portion in the thickness direction of the substrate.

The first non-refractive portion may be located at a center of the first metalens layer, and the first refractive portion may surround the first non-refractive portion.

The plurality of first nanostructures may have a first width, a first height, and a first spacing.

Minimum values of the first width, the first height and the first spacing may range from 50 nm to 300 nm.

The plurality of second nanostructures may have a second width, a second height, and a second spacing.

The optical device may further include an intermediate layer disposed between the first metalens layer and the second metalens layer. A refractive index of the intermediate layer may be lower than a refractive index of the plurality of first nanostructures.

The intermediate layer may contain gas.

The intermediate layer may include at least one organic film.

The intermediate layer may include at least one inorganic film.

The second metalens layer may include a sub-substrate where the plurality of second nanostructures is disposed on a surface.

The optical device may further include a spacer disposed between the sub-substrate and the sub-substrate to maintain a gap between the substrate and the sub-substrate.

A thickness of the sub-substrate may be smaller than a thickness of the substrate.

The optical device may further include a third metalens layer overlapping with the first metalens layer and the second metalens layer in the thickness direction of the substrate and including a plurality of third nanostructures. The third metalens layer may include a second refractive portion where the plurality of third nanostructures is disposed to refract incident light, and a second non-refractive portion where the plurality of third nanostructures is not disposed.

The plurality of second nanostructures may overlap with the second refractive portion and the second non-refractive portion in the thickness direction of the substrate.

The second non-refractive portion may be located at a center of the third metalens layer, and the second refractive portion may surround the second non-refractive portion.

The second non-refractive portion may overlap with the first non-refractive portion in the thickness direction of the substrate.

The second non-refractive portion may overlap with some of the plurality of first nanostructures in the thickness direction of the substrate.

The plurality of third nanostructures may have a third width, a third height, and a third spacing.

According to one or more embodiments of the present disclosure, there is provided a display device including a display panel for displaying images, and an optical device disposed on a surface of the display panel and configured to change a light path of light output from the display panel. The optical device may include a substrate, a first metalens layer disposed on a surface of the substrate and including a plurality of first nanostructures, and a second metalens layer disposed on the surface of the substrate, overlapping with the first metalens layer in a thickness direction of the substrate and including a plurality of second nanostructures. The first metalens layer may include a first refractive portion where the plurality of first nanostructures is disposed to refract incident light, and a first non-refractive portion where the plurality of first nanostructures is not disposed. The plurality of second nanostructures may overlap with the first refractive portion and the first non-refractive portion in the thickness direction of the substrate.

According to one or more embodiments of the present disclosure, there is provided an electronic device including a display device, the display device including a display panel for displaying images, and an optical device disposed on a surface of the display panel and configured to change a light path of light output from the display panel. The optical device may include a substrate, a first metalens layer disposed on a surface of the substrate and including a plurality of first nanostructures, and a second metalens layer disposed on the surface of the substrate, overlapping with the first metalens layer in a thickness direction of the substrate and including a plurality of second nanostructures. The first metalens layer may include a first refractive portion where the plurality of first nanostructures is disposed to refract incident light, and a first non-refractive portion where the plurality of first nanostructures is not disposed. The plurality of second nanostructures may overlap with the first refractive portion and the first non-refractive portion in the thickness direction of the substrate.

These and other aspects, embodiments and advantages of the present disclosure will become immediately apparent to those of ordinary skill in the art upon review of the Detailed Description and Claims to follow.

According to some embodiments of the present disclosure, an additional metalens layer is disposed at the circumference of a lens in an optical device, so that light passing through the circumference of the lens can be additionally refracted. By doing so, it is possible to address spherical aberration that previously occurred when the focal points of light passing through the circumference of the lens and light passing through the center of the lens were separated from each other.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view of an optical device according to some embodiments of the present disclosure.

FIG. 2 is a plan view of the first metalens layer of FIG. 1.

FIG. 3 is a plan view of the second metalens layer of FIG. 1.

FIG. 4 is a cross-sectional view of the optical device, taken along line I-I′ of FIGS. 2 and 3.

FIG. 5 is a cross-sectional view of the optical device, taken along line I-I′ of FIGS. 2 and 3.

FIG. 6 is a cross-sectional view of the optical device, taken along line I-I′ of FIGS. 2 and 3.

FIG. 7 is a cross-sectional view of the optical device, taken along line I-I′ of FIGS. 2 and 3.

FIG. 8 is a cross-sectional view of the optical device, taken along line I-I′ of FIGS. 2 and 3.

FIG. 9 is a plan view of the first metalens layer of FIG. 1.

FIG. 10 is a plan view of the second metalens layer of FIG. 1.

FIG. 11 is a cross-sectional view of the optical device, taken along line I-I′ of FIGS. 9 and 10.

FIG. 12 is a cross-sectional view of the optical device, taken along line I-I′ of FIGS. 9 and 10.

FIG. 13 is a cross-sectional view of the optical device, taken along line I-I′ of FIGS. 9 and 10.

FIG. 14 is a perspective view of an optical device according to some embodiments of the present disclosure.

FIG. 15 is a plan view of the third metalens layer of FIG. 14.

FIG. 16 is a cross-sectional view of the optical device, taken along line I-I′ of FIGS. 2, 3, and 15.

FIG. 17 is a cross-sectional view of the optical device, taken along line I-I′ of FIGS. 2, 3, and 15.

FIG. 18 is a cross-sectional view of the optical device, taken along line I-I′ of FIGS. 2, 3, and 15.

FIG. 19 is a cross-sectional view of the optical device, taken along line I-I′ of FIGS. 2, 3 and 15.

FIG. 20 is a cross-sectional view of the optical device, taken along line I-I′ of FIGS. 2, 3, and 15.

FIG. 21 is a cross-sectional view of the optical device, taken along line I-I′ of FIGS. 2, 3, and 15.

FIG. 22 is a cross-sectional view of the optical device, taken along line I-I′ of FIGS. 2, 3, and 15.

FIG. 23 is a cross-sectional view of the optical device, taken along line I-I′ of FIGS. 2, 3, and 15.

FIG. 24 is a cross-sectional view of the optical device, taken along line I-I′ of FIGS. 9, 10, and 15.

FIG. 25 is a cross-sectional view of the optical device, taken along line I-I′ of FIGS. 9, 10, and 15.

FIG. 26 is a cross-sectional view of the optical device, taken along line I-I′ of FIGS. 9, 10, and 15.

FIG. 27 is a cross-sectional view of the optical device, taken along line I-I′ of FIGS. 9, 10, and 15.

FIG. 28 is a cross-sectional view of the optical device, taken along line I-I′ of FIGS. 9, 10, and 15.

FIG. 29 is a cross-sectional view of the optical device, taken along line I-I′ of FIGS. 9, 10, and 15.

FIG. 30 is a cross-sectional view of the optical device, taken along line I-I′ of FIGS. 9, 10, and 15.

FIG. 31 is a cross-sectional view of the optical device, taken along line I-I′ of FIGS. 9, 10, and 15.

FIG. 32 is a cross-sectional view of a display device including an optical device according to some embodiments of the present disclosure.

FIG. 33 is a cross-sectional view of the display panel of FIG. 32.

FIG. 34 is a view showing an example of an electronic device including a display device according to some embodiments of the present disclosure.

### DETAILED DESCRIPTION OF THE EMBODIMENTS

Aspects and features of embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. §132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

Specific embodiments are described below with reference to the attached drawings.

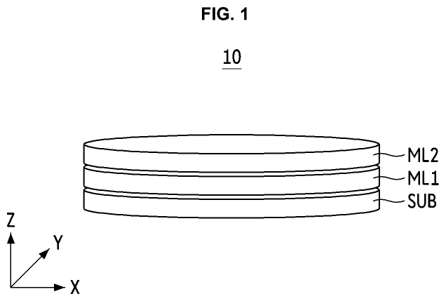

FIG. 1 is a perspective view of an optical device according to some embodiments of the present disclosure.

Referring to FIG. 1, an optical device 10 according to some embodiments of the present disclosure includes a substrate SUB, a first metalens layer ML1, and a second metalens layer ML2.

The first metalens layer ML1 may be disposed (e.g., located or arranged) on a surface of the substrate SUB. The substrate SUB may include a material that allows light to pass through it, such as glass and plastic.

The first metalens layer ML1 may be disposed on the substrate SUB. The shape of the first metalens layer ML1 may follow the shape of the substrate SUB when viewed from the top.

The first metalens layer ML1 may include a plurality of nanostructures. The refractive index of the first metalens layer ML1 may vary depending on the arrangement of the plurality of nanostructures.

The second metalens layer ML2 may be disposed on the first metalens layer ML1. The shape of the second metalens layer ML2 may follow the shape of the first metalens layer ML1 when viewed from the top.

The second metalens layer ML2 may include a plurality of nanostructures. The refractive index of the second metalens layer ML2 may vary depending on the arrangement of the plurality of nanostructures.

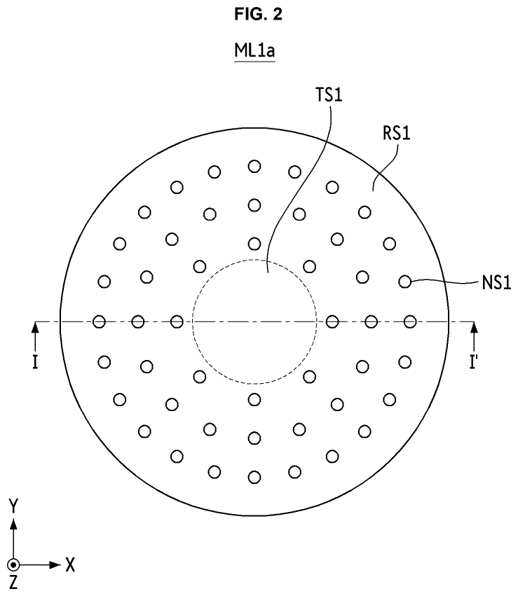

FIG. 2 is a plan view of the first metalens layer of FIG. 1.

Referring to FIG. 2, the first metalens layer ML1a may include a first refractive portion RS1 and a first non-refractive portion TS1.

The first non-refractive portion TS1 may be disposed at the center of the first metalens layer ML1a. In the first non-refractive portion TS1, no first nanostructure NS1 may be disposed. Although the first non-refractive portion TS1 has a circular shape in the example shown in FIG. 2, the shape of the first non-refractive portion TS1 when viewed from the top is not limited thereto.

In the first non-refractive portion TS1, no first nanostructure NS1 is disposed, and thus light may not be refracted. Accordingly, light passing through the first non-refractive portion TS1 may pass through it without being refracted.

The first refractive portion RS2 may surround the first non-refractive portion TS1. The first refractive portion RS1 may be disposed along the circumference of the first metalens layer ML1a.

The first refractive portion RS1 may include a plurality of first nanostructures NS1. The plurality of first nanostructures NS1 may have a first width, a first height and a first spacing. For example, the minimum values of the first width, the first height, and the first spacing may range from 50 nm to 300 nm. The plurality of first nanostructures NS1 may be formed by using, but is not limited to, lithography equipment. The plurality of first nanostructures NS1 may have a variety of shapes, such as a circular column, a rectangular column, and a bracket. The plurality of first nanostructures NS1 may include, for example, at least one of a silicon oxide-based material, a silicon nitride-based material, and a titanium oxide-based material.

In the first refractive portion RS1, the plurality of first nanostructures NS1 is disposed and thus light may be refracted. Specifically, the phase of the light may be adjusted depending on the difference between the refractive index of the plurality of first nanostructures NS1 and the refractive index of the material in the vicinity of the first nanostructure NS1, so that the light paths may be adjusted.

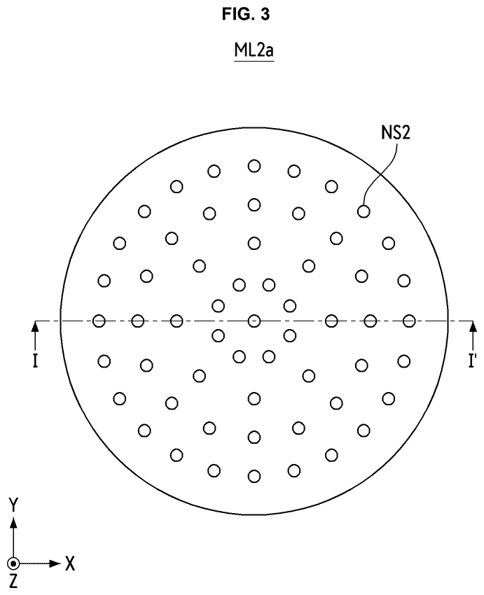

FIG. 3 is a plan view of the second metalens layer of FIG. 1.

Referring to FIG. 3, the second metalens layer ML2a may include a plurality of second nanostructures NS2. The plurality of second nanostructures NS2 may be disposed at both the center and the circumference of the second metalens layer ML2a. The plurality of second nanostructures NS2 may overlap with the first non-refractive portion TS1 of the first metalens layer ML1a in the thickness direction (z-axis direction) of the substrate SUB. The plurality of second nanostructures NS2 may overlap with the first refractive portion RS1 of the first metalens layer ML1a in the thickness direction (z-axis direction) of the substrate SUB.

The plurality of second nanostructures NS2 may have a second width, a second height, and a second spacing. For example, the minimum values of the second width, the second height, and the second spacing may range from 50 nm to 300 nm. The plurality of second nanostructures NS2 may be formed by using, but is not limited to, lithography equipment. The plurality of second nanostructures NS2 may have a variety of shapes, such as a circular column, a rectangular column, and a bracket. The plurality of second nanostructures NS2 may include, for example, at least one of a silicon oxide-based material, a silicon nitride-based material, and a titanium oxide-based material.

In the second metalens layer ML2a, a plurality of second nanostructures NS2 is disposed and thus light may be refracted. Specifically, the phase of the light may be adjusted depending on the difference between the refractive index of the plurality of second nanostructures NS2 and the refractive index of the material in the vicinity of the second nanostructure NS2, so that the light paths may be adjusted.

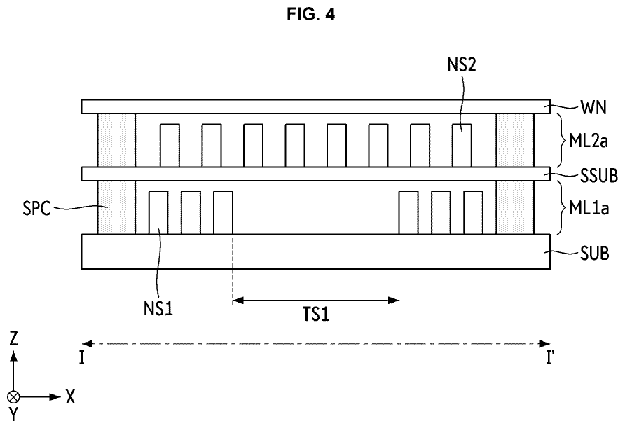

FIG. 4 is a cross-sectional view of the optical device, taken along line I-I′ of FIGS. 2 and 3. The following description will focus on differences and the redundant description will not be provided.

Referring to FIG. 4, the optical device 10 may include the substrate SUB, the first metalens layer ML1a, the second metalens layer ML2a and the window member WN.

The first metalens layer ML1a may be disposed on the substrate SUB. The first metalens layer ML1a may include a plurality of first nanostructures NS1 and a spacer SPC. The first metalens layer ML1a may include a first non-refractive portion TS1 where the plurality of first nanostructures NS1 is not disposed.

The second metalens layer ML2a may be disposed on the first metalens layer ML1a. The second metalens layer ML2a may include a sub-substrate SSUB, a plurality of second nanostructures NS2, and a spacer SPC. The plurality of second nanostructures NS2 may be disposed on the sub-substrate SSUB. The sub-substrate SSUB may include a material that allows light to pass through it, such as glass and plastic. The thickness of the sub-substrate SSUB may be smaller than the thickness of the substrate SUB.

The plurality of second nanostructures NS2 may overlap with the first non-refractive portion TS1 and the plurality of first nanostructures NS1 in the thickness direction (z-axis direction) of the substrate SUB.

The spacer SPC may be disposed between the substrate SUB and the sub-substrate SSUB. The spacer SPC may be in contact with the upper surface of the substrate SUB. The spacer SPC may be in contact with the lower surface of the sub-substrate SSUB. The spacer SPC may maintain the gap between the substrate SUB and the sub-substrate SSUB. In addition, the spacer SPC may protect the first metalens layer ML1a by mitigating shock applied to the first metalens layer ML1a when the shock is applied to the optical device 10.

The first metalens layer ML1a surrounded by the substrate SUB, the sub-substrate SSUB and the spacer SPC may be filled with a gas. The gas may have a lower refractive index than the plurality of first nanostructures NS1. For example, the gas may be air.

The window member WN may be disposed on the second metalens layer ML2a. The window member WN may include a material that allows light to pass through it. The window member WN may prevent foreign substances from permeating into the second metalens layer ML2a.

The spacer SPC may be disposed between the sub-substrate SSUB and the window member WN. The spacer SPC may be in contact with the upper surface of the sub-substrate SSUB. The spacer SPC may be in contact with the lower surface of the window member WN. The spacer SPC can maintain the gap between the sub-substrate SSUB and the window member WN. In addition, the spacer SPC can protect the second metalens layer ML2a by mitigating shock applied to the second metalens layer ML2a when the shock is applied to the optical device 10.

The second metalens layer ML2a surrounded by the sub-substrate SSUB, the window member WN and the spacer SPC may be filled with a gas. The gas may have a lower refractive index than the plurality of second nanostructures NS2. For example, the gas may be air.

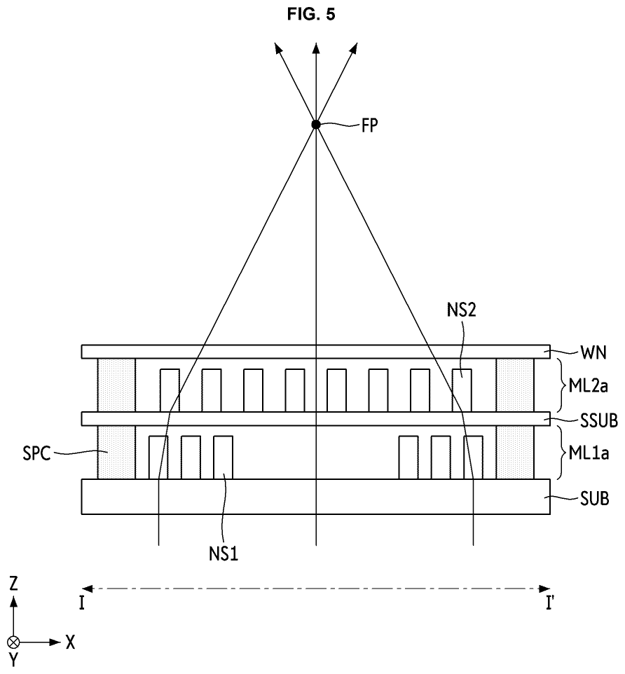

### FIG. 5 is a cross-sectional view of the optical device, taken along Line I-I′ of FIGS. 2 and 3.

FIG. 5 shows an example of light paths along which light propagates in the optical device 10 of FIG. 4. Referring to FIG. 5, light incident on the lower left side of the optical device 10 may pass through the first nanostructures NS1 of the first metalens layer ML1a, and may be refracted based on the difference between the refractive index of the first nanostructures NS1 and the refractive index of the gas in the first metalens layer ML1a. In addition, the light refracted through the first nanostructures NS1 may pass through the second nanostructures NS2 disposed on the sub-substrate SSUB, and may be refracted based on the difference between the refractive index of the second nanostructures NS2 and the refractive index of the gas in the second metalens layer ML2a. Accordingly, the light incident on the lower left side of the optical device 10 may be refracted twice.

Likewise, light incident on the lower right side of the optical device 10 may be refracted through the first nanostructures NS1 of the first metalens layer ML1a. In addition, light refracted through the first nanostructures NS1 may be refracted once more while passing through the second nanostructures NS2 disposed on the sub-substrate SSUB. Accordingly, the light incident on the lower right side of the optical device 10 may be refracted twice.

On the other hand, light incident on the center of the optical device 10 may pass through the first non-refractive portion TS1 of the first metalens layer ML1a without being refracted. In addition, light passing through the first non-refractive portion TS1 may pass through the second nano structures NS2 disposed on the sub-substrate SSUB. Refraction through the second nanostructures NS2 may or may not occur depending on the angle of incidence at which the light passing through the first non-refractive portion TS1 is incident on the second nanostructures NS2. If the light passing through the first non-refractive portion TS1 is incident perpendicularly on the second nanostructures NS2, the light may pass through the second nanostructures NS2 without being refracted. If the light passing through the first non-refractive portion TS1 is incident obliquely on the second nanostructures NS2, the light may be refracted through the second nanostructures NS2.

In the existing metalenses, spherical aberration had occurred (e.g., the focus of light passing through the circumference of the lens was separated from the focus of light passing through the center of the lens). According to this embodiment, since the first non-refractive portion TS1 is formed at the center of the first metalens layer ML1a, light passing through the circumference of the lens may be refracted twice, while light passing through the center of the lens may be refracted only once. In this manner, the light passing through the circumference of the lens and the light passing through the center of the lens may propagate to a single focus FP, thereby addressing the spherical aberration.

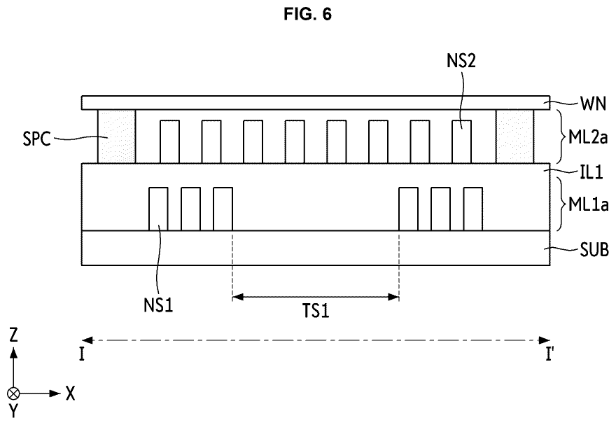

FIG. 6 is a cross-sectional view of the optical device, taken along line I-I′ of FIGS. 2 and 3. The following description will focus on differences and the redundant description will not be provided.

Referring to FIG. 6, an optical device 10 according to some embodiments of the present disclosure may include a substrate SUB, a first metalens layer ML1a, a first intermediate layer IL1, a second metalens layer ML2a, and a window member WN.

Compared to FIG. 4, the optical device 10 of FIG. 6 may include the first intermediate layer IL1 instead of the spacer SPC of the sub-substrate SSUB and the first metalens layer ML1a.

The first intermediate layer IL1 may be disposed on the substrate SUB. The first intermediate layer IL1 may cover a plurality of first nanostructures NS1 and a first non-refractive portion TS1, and may provide a flat upper surface of the first metalens layer ML1a. A plurality of second nanostructures NS2 may be disposed on the first intermediate layer IL1.

The refractive index of the first intermediate layer IL1 may be lower than the refractive index of the plurality of first nanostructures NS1. For example, the first intermediate layer IL1 may include an organic material that can transmit light. In some embodiments, the first intermediate layer IL1 may include an inorganic material that can transmit light.

The second metalens layer ML2a may include a plurality of second nanostructures NS2 and a spacer SPC.

The spacer SPC may be disposed between the first intermediate layer IL1 and the window member WN. The spacer SPC may be in contact with the upper surface of the first intermediate layer IL1. The spacer SPC may be in contact with the lower surface of the window member WN. The spacer SPC can maintain the gap between the first intermediate layer IL1 and the window member WN. In addition, the spacer SPC can protect the second metalens layer ML2a by mitigating shock applied to the second metalens layer ML2a when the shock is applied to the optical device 10.

The second metalens layer ML2a surrounded by the first intermediate layer IL1, the window member WN and the spacer SPC may be filled with a gas. The gas may have a lower refractive index than the plurality of second nanostructures NS2. For example, the gas may be air.

The phase of the light passing through the first refractive portion RS1 of the first metalens layer ML1a may be adjusted depending on the difference between the refractive index of the plurality of first nanostructures NS1 and the refractive index of the first intermediate layer IL1, so that the light paths may be adjusted (e.g., refracted).

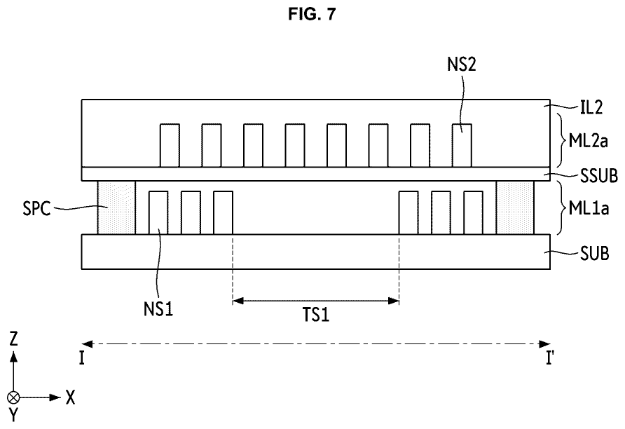

FIG. 7 is a cross-sectional view of the optical device, taken along line I-I′ of FIGS. 2 and 3. The following description will focus on differences and the redundant description will not be provided.

Referring to FIG. 7, an optical device 10 according to some embodiments of the present disclosure may include a substrate SUB, a first metalens layer ML1a, a second metalens layer ML2a, and a second intermediate layer IL2.

Compared to FIG. 4, the optical device 10 of FIG. 7 may include the second intermediate layer IL2 instead of the spacer SPC of the window member WN and the second metalens layer ML2a.

The second intermediate layer IL2 may be disposed on the sub-substrate SSUB. The second metalens layer ML2a may include a sub-substrate SSUB, and a plurality of second nanostructures NS2. The second intermediate layer IL2 may cover a plurality of second nanostructures NS2 and may provide a flat upper surface of the second metalens layer ML2a.

The refractive index of the second intermediate layer IL2 may be lower than the refractive index of the plurality of second nanostructures NS2. For example, the second intermediate layer IL2 may include an organic material that can transmit light. In some embodiments, the second intermediate layer IL2 may include an inorganic material that can transmit light.

The phase of the light passing through the second metalens layer ML2a may be adjusted depending on the difference between the refractive index of the plurality of second nanostructures NS2 and the refractive index of the second intermediate layer IL2, so that the light paths may be adjusted (e.g., refracted).

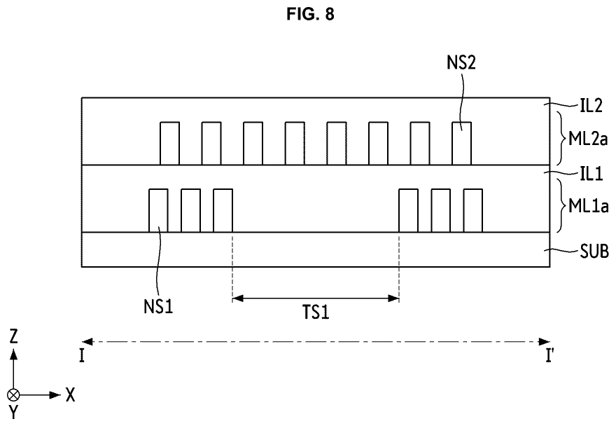

FIG. 8 is a cross-sectional view of the optical device, taken along line I-I′ of FIGS. 2 and 3. The following description will focus on differences and the redundant description will not be provided.

Referring to FIG. 8, an optical device 10 according to some embodiments of the present disclosure may include a substrate SUB, a first metalens layer ML1a, a first intermediate layer IL1, a second metalens layer ML2a, and a second intermediate layer IL2.

Compared with FIG. 6, FIG. 8 may include the second intermediate layer IL2 instead of the spacer SPC of the window member WN and the second metalens layer ML2a.

Compared with FIG. 7, FIG. 8 may include the first intermediate layer IL1 instead of the spacer SPC of the sub-substrate SSUB and the first metalens layer ML1a.

The first intermediate layer IL1 may be disposed on the substrate SUB. The first intermediate layer IL1 may cover a plurality of first nanostructures NS1 and a first non-refractive portion TS1, and may provide a flat upper surface of the first metalens layer ML1a. A plurality of second nanostructures NS2 may be disposed on the first intermediate layer IL1. The first intermediate layer IL1 of FIG. 8 may be substantially identical to the first intermediate layer IL1 of FIG. 6.

The second intermediate layer IL2 may be disposed on the first intermediate layer IL1. The second intermediate layer IL2 may cover a plurality of second nanostructures NS2 and may provide a flat upper surface of the second metalens layer ML2a. The second intermediate layer IL2 of FIG. 8 may be substantially identical to the second intermediate layer IL2 of FIG. 7.

The phase of the light passing through the first refractive portion RS1 of the first metalens layer ML1a may be adjusted depending on the difference between the refractive index of the plurality of first nanostructures NS1 and the refractive index of the first intermediate layer IL1, so that the light paths may be adjusted (e.g., refracted).

The phase of the light passing through the second metalens layer ML2a may be adjusted depending on the difference between the refractive index of the plurality of second nanostructures NS2 and the refractive index of the second intermediate layer IL2, so that the light paths may be adjusted (e.g., refracted).

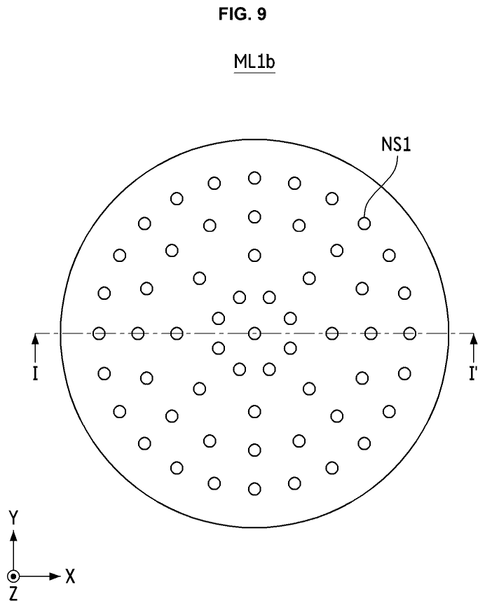

FIG. 9 is a plan view of the first metalens layer of FIG. 1. The following description will focus on differences and the redundant description will not be provided.

Referring to FIG. 9, the first metalens layer ML1b may include a plurality of first nanostructures NS1. The plurality of first nanostructures NS1 may be disposed at both the center and the circumference of the first metalens layer ML1b.

The first nanostructures NS1 of FIG. 9 may be substantially identical to the second nanostructures NS2 of FIG. 3.

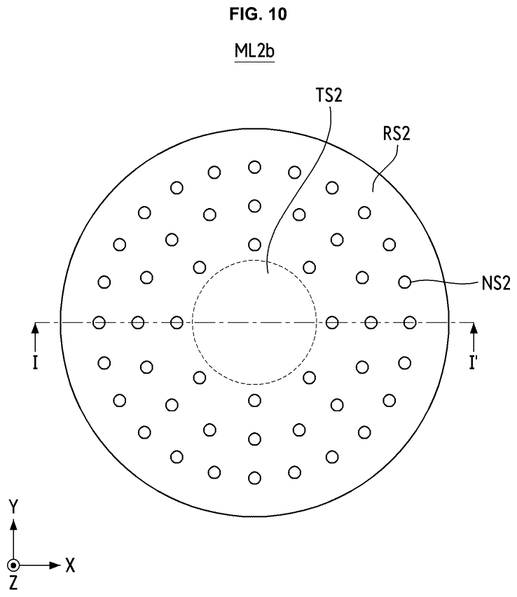

FIG. 10 is a plan view of the second metalens layer of FIG. 1. The following description will focus on differences and the redundant description will not be provided.

Referring to FIG. 10, the second metalens layer ML2b may include a second refractive portion RS2 and a second non-refractive portion TS2.

The second non-refractive portion TS2 may be disposed at the center of the second metalens layer ML2b. In the second non-refractive portion TS2, no second nanostructure NS2 may be disposed. Although the second non-refractive portion TS2 has a circular shape in the example shown in FIG. 10, the shape of the second non-refractive portion TS2 when viewed from the top is not limited thereto.

In the second non-refractive portion TS2, no second nanostructure NS2 is disposed, and thus light may not be refracted. Accordingly, light passing through the second non-refractive portion TS2 may pass through it without being refracted.

The second non-refractive portion TS2 of FIG. 10 may be substantially identical to the first non-refractive portion TS1 of FIG. 3.

The second refractive portion RS2 may surround the second non-refractive portion TS2. The second refractive portion RS2 may be disposed along the circumference of the second metalens layer ML2b. The second refractive portion RS2 may include a plurality of second nanostructures NS2.

The plurality of second nanostructures NS2 of FIG. 10 may be substantially identical to the plurality of first nanostructures NS1 of FIG. 2.

In the second refractive portion RS2, the plurality of second nanostructures NS2 is disposed and thus light may be refracted. Specifically, the phase of the light may be adjusted depending on the difference between the refractive index of the plurality of second nanostructures NS2 and the refractive index of the material in the vicinity of the second nanostructure NS2, so that the light paths may be adjusted.

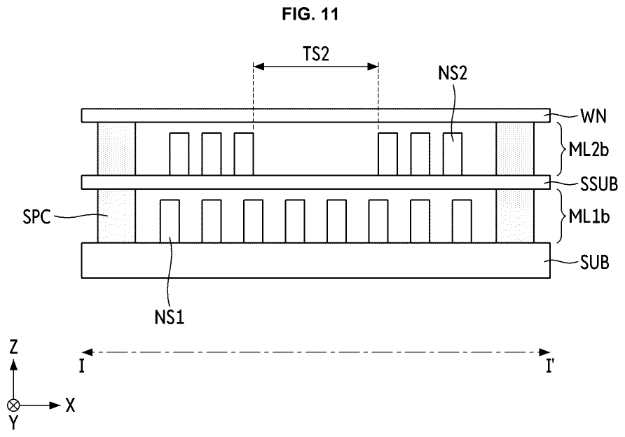

FIG. 11 is a cross-sectional view of the optical device, taken along line I-I′ of FIGS. 9 and 10. The following description will focus on differences and the redundant description will not be provided.

Referring to FIG. 11, the optical device 10 may include the substrate SUB, the first metalens layer ML1b, the second metalens layer ML2b and the window member WN.

The first metalens layer ML1b may be disposed on the substrate SUB. The first metalens layer ML1b may include a plurality of first nanostructures NS1 and a spacer SPC. The plurality of first nanostructures NS1 may be disposed at both the center and the circumference of the first metalens layer ML1b.

The second metalens layer ML2b may be disposed on the first metalens layer ML1b. The second metalens layer ML2b may include a sub-substrate SSUB, a plurality of second nanostructures NS2, and a spacer SPC. The second metalens layer ML2b may include a second non-refractive portion TS2 where a plurality of second nanostructures NS2 is not disposed. The plurality of second nanostructures NS2 may be disposed on the sub-substrate SSUB.

The spacer SPC may be disposed between the substrate SUB and the sub-substrate SSUB. The substrate SUB and the sub-substrate SSUB may be substantially identical to those of the above-described embodiments.

The first metalens layer ML1b surrounded by the substrate SUB, the sub-substrate SSUB and the spacer SPC may be filled with a gas. The gas may have a lower refractive index than the plurality of first nanostructures NS1. For example, the gas may be air.

The window member WN may be disposed on the second metalens layer ML2b. The spacer SPC may be disposed between the sub-substrate SSUB and the window member WN.

The second metalens layer ML2b surrounded by the sub-substrate SSUB, the window member WN and the spacer SPC may be filled with a gas. The gas may have a lower refractive index than the plurality of second nanostructures NS2. For example, the gas may be air.

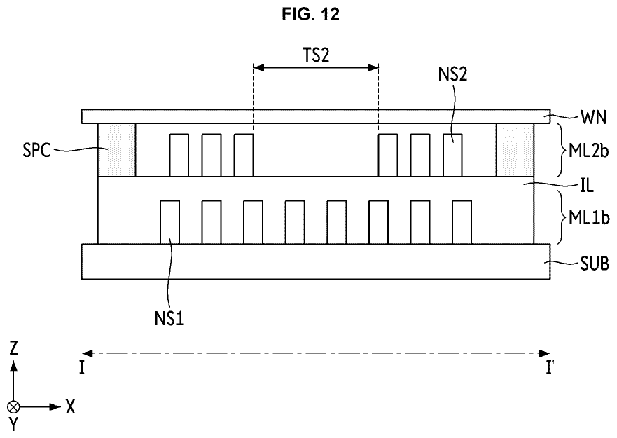

FIG. 12 is a cross-sectional view of the optical device, taken along line I-I′ of FIGS. 9 and 10. The following description will focus on differences and the redundant description will not be provided.

Referring to FIG. 12, an optical device 10 according to some embodiments of the present disclosure may include a substrate SUB, a first metalens layer ML1b, a first intermediate layer IL1, a second metalens layer ML2b, and a window member WN.

Compared to FIG. 11, the optical device 10 of FIG. 12 may include the first intermediate layer IL1 instead of the spacer SPC of the sub-substrate SSUB and the first metalens layer ML1b.

The first intermediate layer IL1 may be disposed on the substrate SUB. The first intermediate layer IL1 may cover a plurality of first nanostructures NS1 and may provide a flat upper surface of the first metalens layer ML1b. A plurality of second nanostructures NS2 may be disposed on the first intermediate layer IL1.

The first intermediate layer IL1 of FIG. 12 may be substantially identical to that of the above-described embodiments.

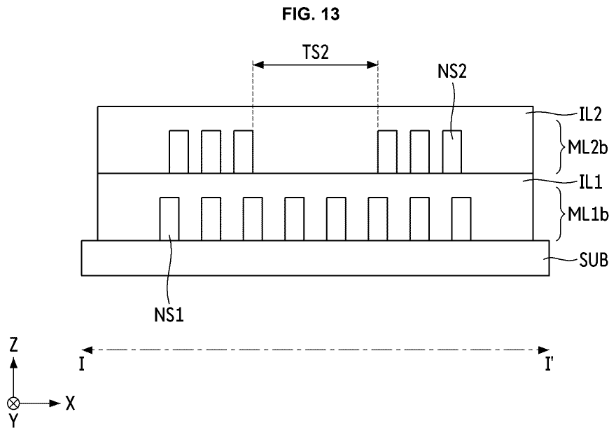

FIG. 13 is a cross-sectional view of the optical device, taken along line I-I′ of FIGS. 9 and 10. The following description will focus on differences and the redundant description will not be provided.

Referring to FIG. 13, an optical device 10 according to some embodiments of the present disclosure may include a substrate SUB, a first metalens layer ML1b, a first intermediate layer IL1, a second metalens layer ML2b, and a second intermediate layer IL2.

Compared to FIG. 12, FIG. 13 may include the second intermediate layer IL2 instead of the spacer SPC of the window member WN and the second metalens layer ML2b.

The second intermediate layer IL2 may be disposed on the first intermediate layer IL1. The second intermediate layer IL2 may cover a plurality of second nanostructures NS2 and a second non-refractive portion TS2, and may provide a flat upper surface of the second metalens layer ML2b.

The second intermediate layer IL2 of FIG. 13 may be substantially identical to the second intermediate layer IL2 of the above-described embodiments.

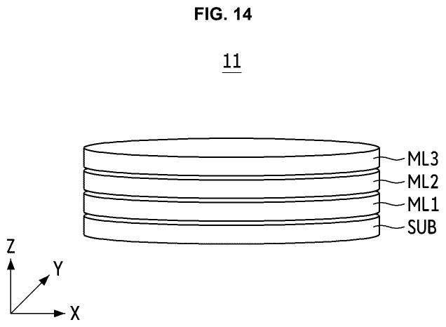

FIG. 14 is a perspective view of an optical device according to some embodiments of the present disclosure. The following description will focus on differences and the redundant description will not be provided.

Referring to FIG. 14, an optical device 11 according to some embodiments of the present disclosure may include a substrate SUB, a first metalens layer ML1, a second metalens layer ML2, and a third metalens layer ML3.

The substrate SUB, the first metalens layer ML1 and the second metalens layer ML3 may be substantially identical to the substrate SUB, the first metalens layer ML1 and the second metalens layer ML3 of the above-described embodiments, respectively.

The third metalens layer ML3 may be disposed on the second metalens layer ML2. The shape of the third metalens layer ML3 may follow the shape of the second metalens layer ML2 when viewed from the top.

The third metalens layer ML3 may include a plurality of nanostructures. The refractive index of the third metalens layer ML3 may vary depending on the arrangement of the plurality of nanostructures.

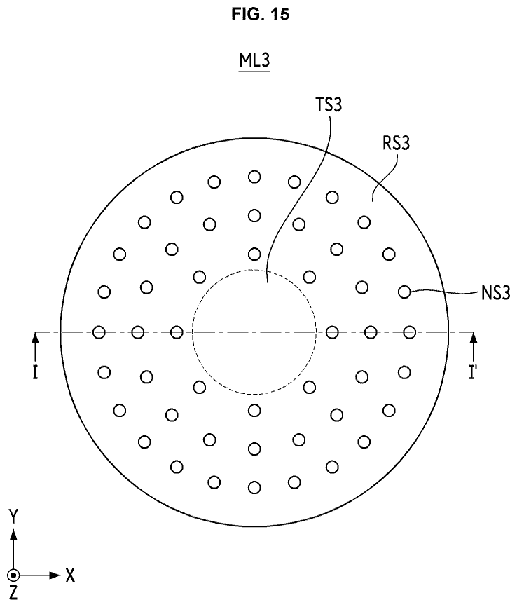

FIG. 15 is a plan view of the third metalens layer of FIG. 14. The following description will focus on differences and the redundant description will not be provided.

Referring to FIG. 15, the third metalens layer ML3 may include a third refractive portion RS3 and a third non-refractive portion TS3.

The third non-refractive portion TS3 may be disposed at the center of the third metalens layer ML3. In the third non-refractive portion TS3, no third nanostructure NS3 may be disposed. Although the third non-refractive portion TS3 has a circular shape in the example shown in FIG. 15, the shape of the third non-refractive portion TS3 when viewed from the top is not limited thereto.

In the third non-refractive portion TS3, no third nanostructure NS3 is disposed, and thus light may not be refracted. Accordingly, light passing through the third non-refractive portion TS3 may pass through it without being refracted.

The third refractive portion RS3 may surround the third non-refractive portion TS3. The third refractive portion RS3 may be disposed along the circumference of the third metalens layer ML3.

The third refractive portion RS3 may include a plurality of third nanostructures NS3. The plurality of third nanostructures NS3 may have a third width, a third height and a third spacing. For example, the minimum values of the third width, the third height, and the third spacing may range from 50 nm to 300 nm. The plurality of third nanostructures NS3 may be formed by using, but is not limited to, lithography equipment. The plurality of third nanostructures NS3 may have a variety of shapes, such as a circular column, a rectangular column, and a bracket. The plurality of third nanostructures NS3 may include, for example, at least one of a silicon oxide-based material, a silicon nitride-based material, and a titanium oxide-based material.

In the third refractive portion RS3, the plurality of third nanostructures NS3 is disposed and thus light may be refracted. Specifically, the phase of the light may be adjusted depending on the difference between the refractive index of the plurality of third nanostructures NS3 and the refractive index of the material surrounding the third nanostructure NS3, so that the light paths may be adjusted.

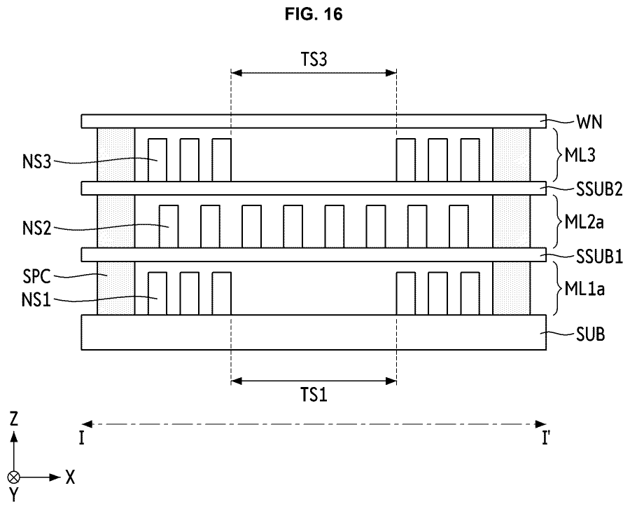

FIG. 16 is a cross-sectional view of the optical device, taken along line I-I′ of FIGS. 2, 3, and 15. The following description will focus on differences and the redundant description will not be provided.

Referring to FIG. 16, an optical device 11 according to some embodiments of the present disclosure may include a substrate SUB, a first metalens layer ML1a, a second metalens layer ML2a, a third metalens layer ML3, and a window member WN.

The first metalens layer ML1a may be disposed on the substrate SUB. The first metalens layer ML1a may include a plurality of first nanostructures NS1 and a spacer SPC. The first metalens layer ML1a may include a first non-refractive portion TS1 where a plurality of first nanostructures NS1 is not disposed. The first metalens layer ML1a of FIG. 16 may be substantially identical to the first metalens layer ML1a described above with reference to FIG. 2.

The second metalens layer ML2a may be disposed on the first metalens layer ML1a. The second metalens layer ML2a may include a first sub-substrate SSUB1, a plurality of second nanostructures NS2, and a spacer SPC.

The first sub-substrate SSUB1 may include a material that allows light to pass through it, such as glass and plastic. The thickness of the first sub-substrate SSUB1 may be smaller than the thickness of the substrate SUB.

The spacer SPC may be disposed between the substrate SUB and the first sub-substrate SSUB1. The spacer SPC may be in contact with the upper surface of the substrate SUB. The spacer SPC may be in contact with the lower surface of the first sub-substrate SSUB1. The spacer SPC can maintain the gap between the substrate SUB and the first sub-substrate SSUB1.

The first metalens layer ML1a surrounded by the substrate SUB, the first sub-substrate SSUB1 and the spacer SPC may be filled with a gas. The gas may have a lower refractive index than the plurality of first nanostructures NS1. For example, the gas may be air.

The plurality of second nanostructures NS2 may be disposed on the first sub-substrate SSUB1. The second metalens layer ML2a of FIG. 16 may be substantially identical to the second metalens layer ML2a described above with reference to FIG. 3.

The third metalens layer ML3 may be disposed on the second metalens layer ML2a. The third metalens layer ML3 may include a second sub-substrate SSUB2, a plurality of third nanostructures NS3, and a spacer SPC.

The second sub-substrate SSUB2 may include a material that allows light to pass through it, such as glass and plastic. The thickness of the second sub-substrate SSUB2 may be smaller than the thickness of the substrate SUB.

The spacer SPC may be disposed between the first sub-substrate SSUB1 and the second sub-substrate SSUB2. The spacer SPC may be in contact with the upper surface of the first sub-substrate SSUB1. The spacer SPC may be in contact with the lower surface of the second sub-substrate SSUB2. The spacer SPC can maintain the gap between the first sub-substrate SSUB1 and the second sub-substrate SSUB2.

The second metalens layer ML2a surrounded by the first sub-substrate SSUB1, the second sub-substrate SSUB 2 and the spacer SPC may be filled with a gas. The gas may have a lower refractive index than the plurality of second nanostructures NS2. For example, the gas may be air.

The plurality of third nanostructures NS3 may be disposed on the second sub-substrate SSUB2. The third metalens layer ML3 may include a third non-refractive portion TS3 where the plurality of third nanostructures NS3 is not disposed.

The window member WN may be disposed on the third metalens layer ML3. The spacer SPC may be disposed between the second sub-substrate SSUB2 and the window member WN. The spacer SPC may be in contact with the upper surface of the second sub-substrate SSUB2. The spacer SPC may be in contact with the lower surface of the window member WN. The spacer SPC can maintain the gap between the second sub-substrate SSUB2 and the window member WN.

The third metalens layer ML3 surrounded by the second sub-substrate SSUB2, the window member WN and the spacer SPC may be filled with a gas. The gas may have a lower refractive index than the plurality of third nanostructures NS3. For example, the gas may be air.

The substrate SUB, the window member WN and the spacer SPC of FIG. 16 may be substantially identical to those described above with reference to FIG. 4.

Although the first non-refractive portion TS1 and the third non-refractive portion TS3 are aligned in the thickness direction of the substrate SUB in the example shown in FIG. 16, the embodiments of the present disclosure are not limited thereto. A part of the third non-refractive portion TS3 may not overlap with the first non-refractive portion TS1. In other words, a part of the third non-refractive portion TS3 may overlap with a plurality of first nanostructures NS1. In addition, the width and shape of the third non-refractive portion TS3 may be different from the width and shape of the first non-refractive portion TS1, respectively.

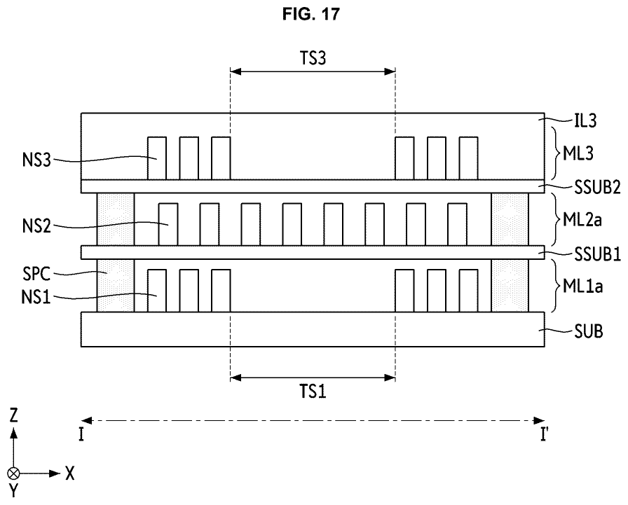

FIG. 17 is a cross-sectional view of the optical device, taken along line I-I′ of FIGS. 2, 3, and 15. The following description will focus on differences and the redundant description will not be provided.

Referring to FIG. 17, an optical device 11 according to some embodiments of the present disclosure may include a substrate SUB, a first metalens layer ML1a, a second metalens layer ML2a, a third metalens layer ML3, and a third intermediate layer IL3.

Compared to FIG. 16, the optical device 11 of FIG. 17 may include the third intermediate layer IL3 instead of the spacer SPC of the window member WN and the third metalens layer ML3.

The third intermediate layer IL3 may be disposed on the second sub-substrate SSUB2. The third intermediate layer IL3 may cover a plurality of third nanostructures NS3 and a third non-refractive portion TS3, and may provide a flat upper surface of the third metalens layer ML3.

The refractive index of the third intermediate layer IL3 may be lower than the refractive index of the plurality of third nanostructures NS3. For example, the third intermediate layer IL3 may include an organic material that can transmit light. In some embodiments, the third intermediate layer IL3 may include an inorganic material that can transmit light.

Although the first non-refractive portion TS1 and the third non-refractive portion TS3 are aligned in the thickness direction of the substrate SUB in the example shown in FIG. 17, the embodiments of the present disclosure are not limited thereto. A part of the third non-refractive portion TS3 may not overlap with the first non-refractive portion TS1. In other words, a part of the third non-refractive portion TS3 may overlap with a plurality of first nanostructures NS1. In addition, the width and shape of the third non-refractive portion TS3 may be different from the width and shape of the first non-refractive portion TS1, respectively.

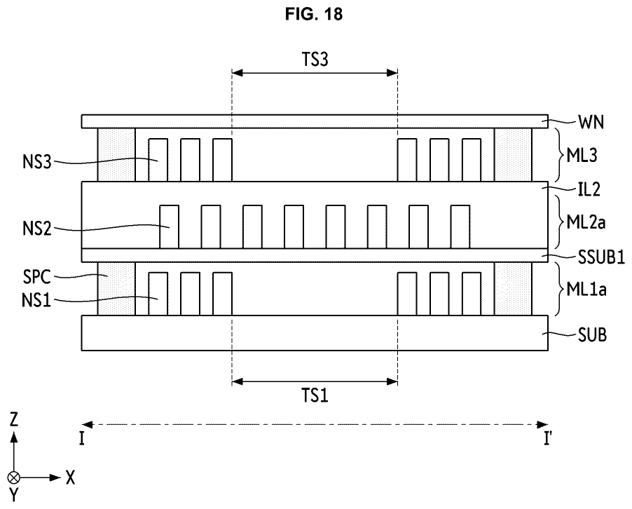

FIG. 18 is a cross-sectional view of the optical device, taken along line I-I′ of FIGS. 2, 3, and 15. The following description will focus on differences and the redundant description will not be provided.

Referring to FIG. 18, an optical device 11 according to some embodiments of the present disclosure may include a substrate SUB, a first metalens layer ML1a, a second metalens layer ML2a, a second intermediate layer IL2, a third metalens layer ML3, and a window member WN.

Compared to FIG. 16, the optical device 11 of FIG. 18 may include the second intermediate layer IL2 instead of the spacer SPC of the second sub-substrate SSUB2 and the second metalens layer ML2a.

The second intermediate layer IL2 may be disposed on the first sub-substrate SSUB1. The second intermediate layer IL2 may cover a plurality of second nanostructures NS2 and may provide a flat upper surface of the second metalens layer ML2a. A plurality of third nanostructures NS3 may be disposed on the second intermediate layer IL2.

The second intermediate layer IL2 of FIG. 18 may be substantially identical to the second intermediate layer IL2 of the above-described embodiments.

Although the first non-refractive portion TS1 and the third non-refractive portion TS3 are aligned in the thickness direction of the substrate SUB in the example shown in FIG. 18, the embodiments of the present disclosure are not limited thereto. A part of the third non-refractive portion TS3 may not overlap with the first non-refractive portion TS1. In other words, a part of the third non-refractive portion TS3 may overlap with a plurality of first nanostructures NS1. In addition, the width and shape of the third non-refractive portion TS3 may be different from the width and shape of the first non-refractive portion TS1, respectively.

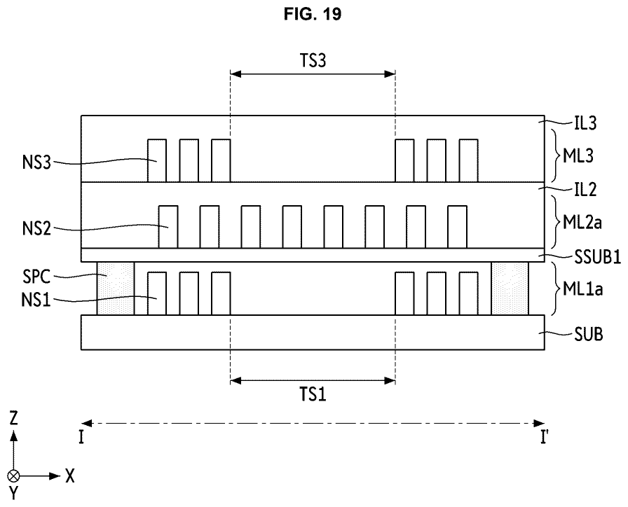

FIG. 19 is a cross-sectional view of the optical device, taken along line I-I′ of FIGS. 2, 3, and 15. The following description will focus on differences and the redundant description will not be provided.

Referring to FIG. 19, an optical device 11 according to some embodiments of the present disclosure may include a substrate SUB, a first metalens layer ML1a, a second metalens layer ML2a, a second intermediate layer IL2, a third metalens layer ML3, and a third intermediate layer IL3.

Compared to FIG. 18, the optical device 11 of FIG. 19 may include the third intermediate layer IL3 instead of the spacer SPC of the window member WN and the third metalens layer ML3.

The third intermediate layer IL3 may be disposed on the second intermediate layer IL2. The third intermediate layer IL3 may cover a plurality of third nanostructures NS3 and a third non-refractive portion TS3, and may provide a flat upper surface of the third metalens layer ML3.

The third intermediate layer IL3 of FIG. 19 may be substantially identical to the third intermediate layer IL3 of the above-described embodiments.

Although the first non-refractive portion TS1 and the third non-refractive portion TS3 are aligned in the thickness direction of the substrate SUB in the example shown in FIG. 19, the embodiments of the present disclosure are not limited thereto. A part of the third non-refractive portion TS3 may not overlap with the first non-refractive portion TS1. In other words, a part of the third non-refractive portion TS3 may overlap with a plurality of first nanostructures NS1. In addition, the width and shape of the third non-refractive portion TS3 may be different from the width and shape of the first non-refractive portion TS1, respectively.

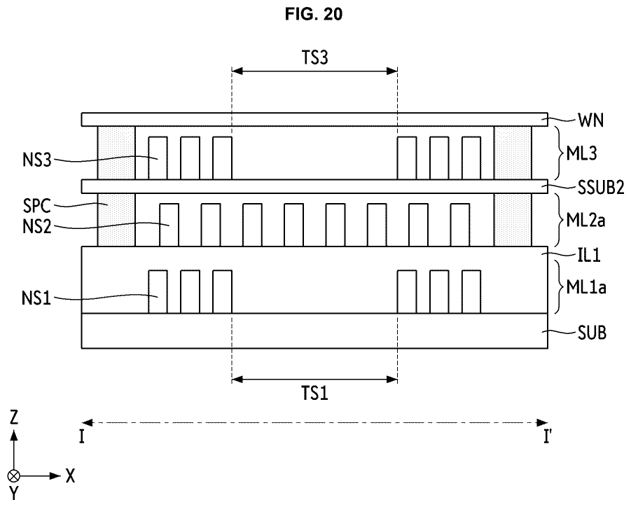

FIG. 20 is a cross-sectional view of the optical device, taken along line I-I′ of FIGS. 2, 3, and 15. The following description will focus on differences and the redundant description will not be provided.

Referring to FIG. 20, an optical device 11 according to some embodiments of the present disclosure may include a substrate SUB, a first metalens layer ML1a, a first intermediate layer IL1, a second metalens layer ML2a, a third metalens layer ML3, and a window member WN.

Compared to FIG. 16, the optical device 11 of FIG. 20 may include the first intermediate layer IL1 instead of the spacer SPC of the first sub-substrate SSUB1 and the first metalens layer ML1a.

The first intermediate layer IL1 may be disposed on the substrate SUB. The first intermediate layer IL1 may cover a plurality of first nanostructures NS1 and a first non-refractive portion TS1, and may provide a flat upper surface of the first metalens layer ML1a. A plurality of second nanostructures NS2 may be disposed on the first intermediate layer IL1. The spacer SPC may be disposed on the first intermediate layer IL1. The spacer SPC may be in contact with the upper surface of the first intermediate layer IL1.

The first intermediate layer IL1 of FIG. 20 may be substantially identical to the first intermediate layer IL1 of the above-described embodiments.

Although the first non-refractive portion TS1 and the third non-refractive portion TS3 are aligned in the thickness direction of the substrate SUB in the example shown in FIG. 20, the embodiments of the present disclosure are not limited thereto. A part of the third non-refractive portion TS3 may not overlap with the first non-refractive portion TS1. In other words, a part of the third non-refractive portion TS3 may overlap with a plurality of first nanostructures NS1. In addition, the width and shape of the third non-refractive portion TS3 may be different from the width and shape of the first non-refractive portion TS1, respectively.

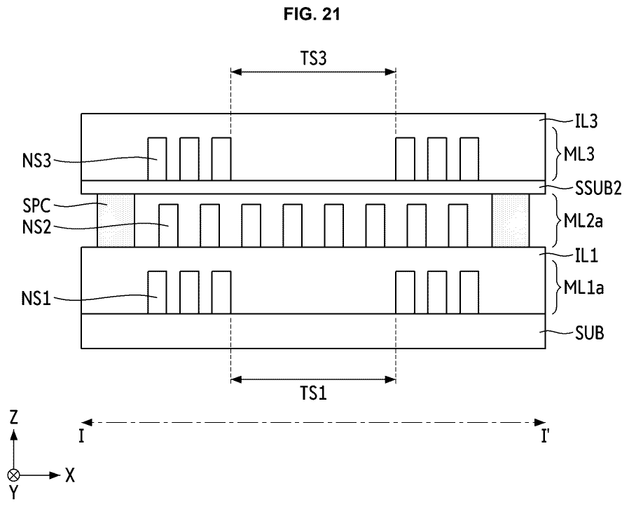

FIG. 21 is a cross-sectional view of the optical device, taken along line I-I′ of FIGS. 2, 3, and 15. The following description will focus on differences and the redundant description will not be provided.

Referring to FIG. 21, an optical device 11 according to some embodiments of the present disclosure may include a substrate SUB, a first metalens layer ML1a, a first intermediate layer IL1, a second metalens layer ML2a, a third metalens layer ML3, and a third intermediate layer IL3.

Compared to FIG. 20, the optical device 11 of FIG. 21 may include the third intermediate layer IL3 instead of the spacer SPC of the window member WN and the third metalens layer ML3.

The third intermediate layer IL3 may be disposed on the second sub-substrate SSUB2. The third intermediate layer IL3 may cover a plurality of nanostructures NS3 and a third non-refractive portion TS3, and may provide a flat upper surface of the third metalens layer ML3.

The third intermediate layer IL3 of FIG. 21 may be substantially identical to the third intermediate layer IL3 of the above-described embodiments.

Although the first non-refractive portion TS1 and the third non-refractive portion TS3 are aligned in the thickness direction of the substrate SUB in the example shown in FIG. 21, the embodiments of the present disclosure are not limited thereto. A part of the third non-refractive portion TS3 may not overlap with the first non-refractive portion TS1. In other words, a part of the third non-refractive portion TS3 may overlap with a plurality of first nanostructures NS1. In addition, the width and shape of the third non-refractive portion TS3 may be different from the width and shape of the first non-refractive portion TS1, respectively.

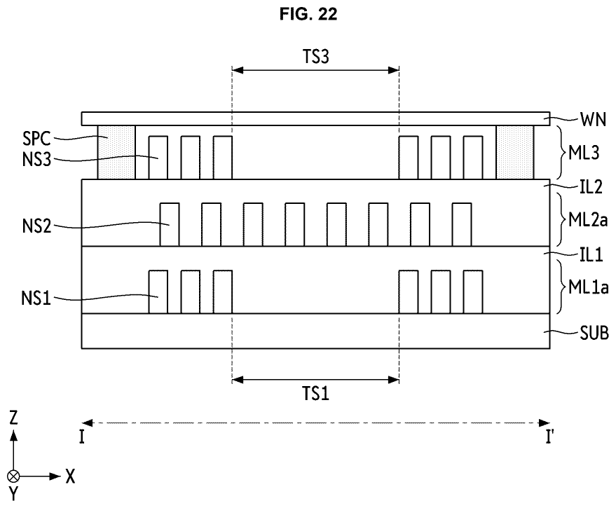

FIG. 22 is a cross-sectional view of the optical device, taken along line I-I′ of FIGS. 2, 3, and 15. The following description will focus on differences and the redundant description will not be provided.

Referring to FIG. 22, an optical device 11 according to some embodiments of the present disclosure may include a substrate SUB, a first metalens layer ML1a, a first intermediate layer IL1, a second metalens layer ML2a, a second intermediate layer IL2, a third metalens layer ML3, and a window member WN.

Compared with FIG. 20, the optical device 11 of FIG. 22 may include the second intermediate layer IL2 instead of the spacer SPC of the second sub-substrate SSUB2 and the second metalens layer ML2a.

The second intermediate layer IL2 may be disposed on the first intermediate layer IL1. The second intermediate layer IL2 may cover a plurality of second nanostructures NS2 and may provide a flat upper surface of the second metalens layer ML2a.

The third metalens layer ML3 may be disposed on the second intermediate layer IL2. Specifically, a plurality of third nanostructures NS3 and the spacer SPC may be disposed on the second intermediate layer IL2.

The second intermediate layer IL2 of FIG. 22 may be substantially identical to the second intermediate layer IL2 of the above-described embodiments.

Although the first non-refractive portion TS1 and the third non-refractive portion TS3 are aligned in the thickness direction of the substrate SUB in the example shown in FIG. 22, the embodiments of the present disclosure are not limited thereto. A part of the third non-refractive portion TS3 may not overlap with the first non-refractive portion TS1. In other words, a part of the third non-refractive portion TS3 may overlap with a plurality of first nanostructures NS1. In addition, the width and shape of the third non-refractive portion TS3 may be different from the width and shape of the first non-refractive portion TS1, respectively.

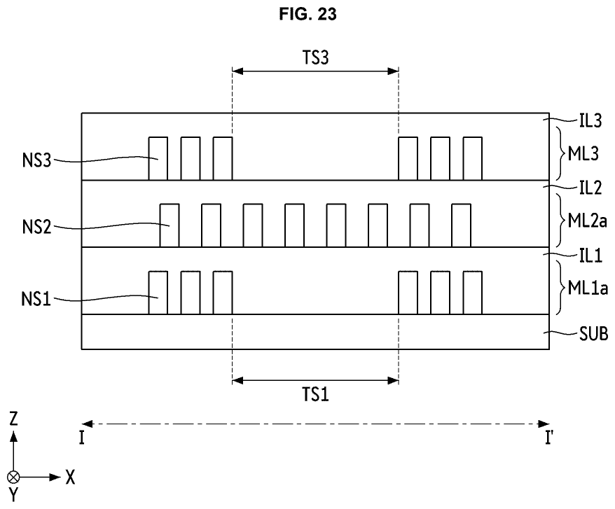

FIG. 23 is a cross-sectional view of the optical device, taken along line I-I′ of FIGS. 2, 3, and 15. The following description will focus on differences and the redundant description will not be provided.

Referring to FIG. 23, an optical device 11 according to some embodiments of the present disclosure may include a substrate SUB, a first metalens layer ML1a, a first intermediate layer IL1, a second metalens layer ML2a, a second intermediate layer IL2, a third metalens layer ML3, and a third intermediate layer IL3.

Compared to FIG. 22, the optical device 11 of FIG. 23 may include the third intermediate layer IL3 instead of the spacer SPC of the window member WN and the third metalens layer ML3.

The third intermediate layer IL3 may be disposed on the second intermediate layer IL2. The third intermediate layer IL3 may cover a plurality of third nanostructures NS3 and a third non-refractive portion TS3, and may provide a flat upper surface of the third metalens layer ML3.

The third intermediate layer IL3 of FIG. 23 may be substantially identical to the third intermediate layer IL3 of the above-described embodiments.

Although the first non-refractive portion TS1 and the third non-refractive portion TS3 are aligned in the thickness direction of the substrate SUB in the example shown in FIG. 23, the embodiments of the present disclosure are not limited thereto. A part of the third non-refractive portion TS3 may not overlap with the first non-refractive portion TS1. In other words, a part of the third non-refractive portion TS3 may overlap with a plurality of first nanostructures NS1. In addition, the width and shape of the third non-refractive portion TS3 may be different from the width and shape of the first non-refractive portion TS1, respectively.

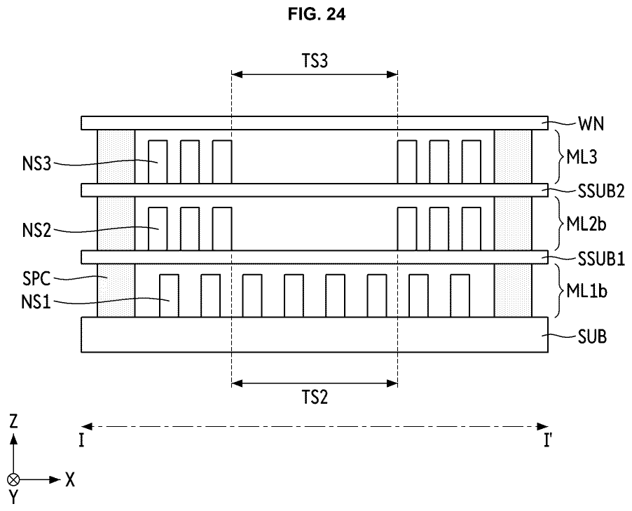

FIG. 24 is a cross-sectional view of the optical device, taken along line I-I′ of FIGS. 9, 10, and 15.

Referring to FIG. 24, an optical device 11 according to some embodiments of the present disclosure may include a substrate SUB, a first metalens layer ML1b, a second metalens layer ML2b, a third metalens layer ML3, and a window member WN.

The first metalens layer ML1b may be disposed on the substrate SUB. The first metalens layer ML1b may include a plurality of first nanostructures NS1 and a spacer SPC. The first metalens layer ML1b of FIG. 24 may be substantially identical to the first metalens layer ML1b described above with reference to FIG. 9.

The second metalens layer ML2b may be disposed on the first metalens layer ML1b. The second metalens layer ML2b may include a first sub-substrate SSUB1, a plurality of second nanostructures NS2, and a spacer SPC.

The spacer SPC may be disposed between the substrate SUB and the first sub-substrate SSUB1. The spacer SPC may be in contact with the upper surface of the substrate SUB. The spacer SPC may be in contact with the lower surface of the first sub-substrate SSUB1. The spacer SPC can maintain the gap between the substrate SUB and the first sub-substrate SSUB1.

The first metalens layer ML1b surrounded by the substrate SUB, the first sub-substrate SSUB1 and the spacer SPC may be filled with a gas. The gas may have a lower refractive index than the plurality of first nanostructures NS1. For example, the gas may be air.

The plurality of second nanostructures NS2 may be disposed on the first sub-substrate SSUB1. The second metalens layer ML2b may include a plurality of second nanostructures NS2. The second metalens layer ML2b may include a second non-refractive portion TS2 where a plurality of second nanostructures NS2 is not disposed. The second metalens layer ML2b of FIG. 24 may be substantially identical to the second metalens layer ML2b described above with reference to FIG. 10.

The third metalens layer ML3 may be disposed on the second metalens layer ML2b. The third metalens layer ML3 may include a second sub-substrate SSUB2, a plurality of third nanostructures NS3, and a spacer SPC.

The spacer SPC may be disposed between the first sub-substrate SSUB1 and the second sub-substrate SSUB2. The spacer SPC may be in contact with the upper surface of the first sub-substrate SSUB1. The spacer SPC may be in contact with the lower surface of the second sub-substrate SSUB2. The spacer SPC can maintain the gap between the first sub-substrate SSUB1 and the second sub-substrate SSUB2.

The second metalens layer ML2b surrounded by the first sub-substrate SSUB1, the second sub-substrate SSUB2 and the spacer SPC may be filled with a gas. The gas may have a lower refractive index than the plurality of second nanostructures NS2. For example, the gas may be air.

The plurality of third nanostructures NS3 may be disposed on the second sub-substrate SSUB2. The third metalens layer ML3 may include a third non-refractive portion TS3 where the plurality of third nanostructures NS3 is not disposed.

The window member WN may be disposed on the third metalens layer ML3. The spacer SPC may be disposed between the second sub-substrate SSUB2 and the window member WN. The spacer SPC may be in contact with the upper surface of the second sub-substrate SSUB2. The spacer SPC may be in contact with the lower surface of the window member WN. The spacer SPC can maintain the gap between the second sub-substrate SSUB2 and the window member WN.

The third metalens layer ML3 surrounded by the second sub-substrate SSUB2, the window member WN and the spacer SPC may be filled with a gas. The gas may have a lower refractive index than the plurality of third nanostructures NS3. For example, the gas may be air.

The substrate SUB, the window member WN and the spacer SPC of FIG. 24 may be substantially identical to those described above with reference to FIGS. 4 and 16.

Although the second non-refractive portion TS2 and the third non-refractive portion TS3 are aligned in the thickness direction of the substrate SUB in the example shown in FIG. 24, the embodiments of the present disclosure are not limited thereto. A part of the third non-refractive portion TS3 may not overlap with the second non-refractive portion TS2. In other words, a part of the third non-refractive portion TS3 may overlap with a plurality of second nanostructures NS2. In addition, the width and shape of the third non-refractive portion TS3 may be different from the width and shape of the second non-refractive portion TS2, respectively.

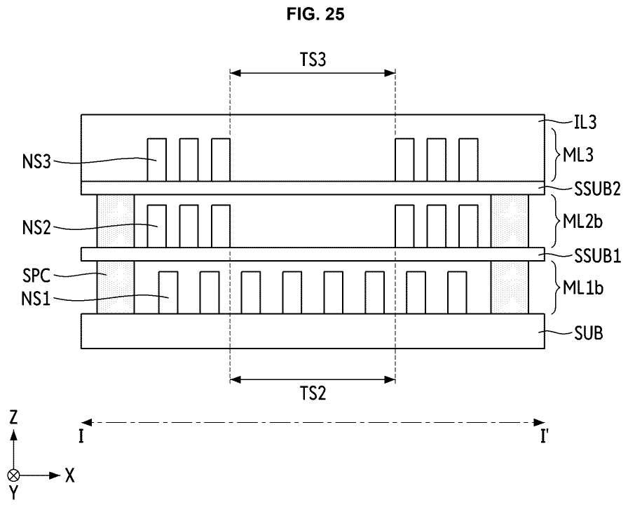

FIG. 25 is a cross-sectional view of the optical device, taken along line I-I′ of FIGS. 9, 10, and 15. The following description will focus on differences and the redundant description will not be provided.

Referring to FIG. 25, an optical device 11 according to some embodiments of the present disclosure may include a substrate SUB, a first metalens layer ML1b, a second metalens layer ML2b, a third metalens layer ML3, and a third intermediate layer IL3.

Compared to FIG. 24, the optical device 11 of FIG. 25 may include the third intermediate layer IL3 instead of the spacer SPC of the window member WN and the third metalens layer ML3.

The third intermediate layer IL3 may be disposed on the second sub-substrate SSUB2. The third intermediate layer IL3 may cover a plurality of third nanostructures NS3 and a third non-refractive portion TS3, and may provide a flat upper surface of the third metalens layer ML3.

The third intermediate layer IL3 of FIG. 25 may be substantially identical to the third intermediate layer IL3 of the above-described embodiments.

Although the second non-refractive portion TS2 and the third non-refractive portion TS3 are aligned in the thickness direction of the substrate SUB in the example shown in FIG. 25, the embodiments of the present disclosure are not limited thereto. A part of the third non-refractive portion TS3 may not overlap with the second non-refractive portion TS2. In other words, a part of the third non-refractive portion TS3 may overlap with a plurality of second nanostructures NS2. In addition, the width and shape of the third non-refractive portion TS3 may be different from the width and shape of the second non-refractive portion TS2, respectively.

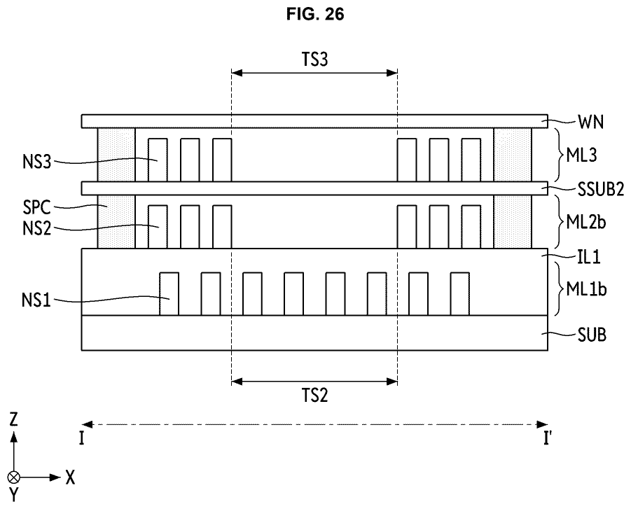

FIG. 26 is a cross-sectional view of the optical device, taken along line I-I′ of FIGS. 9, 10, and 15. The following description will focus on differences and the redundant description will not be provided.

Referring to FIG. 26, an optical device 11 according to some embodiments of the present disclosure may include a substrate SUB, a first metalens layer ML1b, a first intermediate layer IL1, a second metalens layer ML2b, a third metalens layer ML3, and a window member WN.

Compared to FIG. 24, the optical device 11 of FIG. 26 may include the first intermediate layer IL1 instead of the first sub-substrate SSUB1 and the spacer SPC in contact with the lower surface of the first sub-substrate SSUB1.

The first intermediate layer IL1 may be disposed on the substrate SUB. A plurality of first nanostructures NS1 may cover the first intermediate layer IL1. The first intermediate layer IL1 may cover a plurality of first nanostructures NS1 and may provide a flat upper surface of the first metalens layer ML1b.

The first intermediate layer IL1 of FIG. 26 may be substantially identical to the first intermediate layer IL1 of the above-described embodiments.

Although the second non-refractive portion TS2 and the third non-refractive portion TS3 are aligned in the thickness direction of the substrate SUB in the example shown in FIG. 26, the embodiments of the present disclosure are not limited thereto. A part of the third non-refractive portion TS3 may not overlap with the second non-refractive portion TS2. In other words, a part of the third non-refractive portion TS3 may overlap with a plurality of second nanostructures NS2. In addition, the width and shape of the third non-refractive portion TS3 may be different from the width and shape of the second non-refractive portion TS2, respectively.

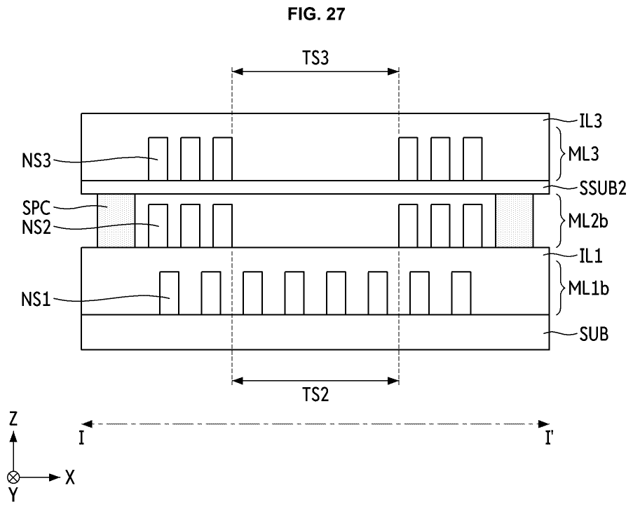

FIG. 27 is a cross-sectional view of the optical device, taken along line I-I′ of FIGS. 9, 10, and 15. The following description will focus on differences and the redundant description will not be provided.

Referring to FIG. 27, an optical device 11 according to some embodiments of the present disclosure may include a substrate SUB, a first metalens layer ML1b, a first intermediate layer IL1, a second metalens layer ML2b, a third metalens layer ML3, and a third intermediate layer IL3.

Compared to FIG. 26, the optical device 11 of FIG. 27 may include the third intermediate layer IL3 instead of the spacer SPC of the window member WN and the third metalens layer ML3.

The third intermediate layer IL3 may be disposed on the second sub-substrate SSUB2. The third intermediate layer IL3 may cover a plurality of third nanostructures NS3 and a third non-refractive portion TS3, and may provide a flat upper surface of the third metalens layer ML3.

The third intermediate layer IL3 of FIG. 27 may be substantially identical to the third intermediate layer IL3 of the above-described embodiments.

Although the second non-refractive portion TS2 and the third non-refractive portion TS3 are aligned in the thickness direction of the substrate SUB in the example shown in FIG. 27, the embodiments of the present disclosure are not limited thereto. A part of the third non-refractive portion TS3 may not overlap with the second non-refractive portion TS2. In other words, a part of the third non-refractive portion TS3 may overlap with a plurality of second nanostructures NS2. In addition, the width and shape of the third non-refractive portion TS3 may be different from the width and shape of the second non-refractive portion TS2, respectively.

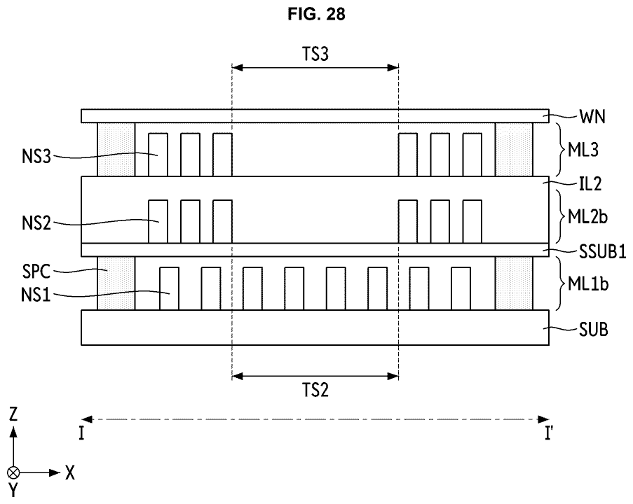

FIG. 28 is a cross-sectional view of the optical device, taken along line I-I′ of FIGS. 9, 10, and 15. The following description will focus on differences and the redundant description will not be provided.

Referring to FIG. 28, an optical device 11 according to some embodiments of the present disclosure may include a substrate SUB, a first metalens layer ML1b, a second metalens layer ML2b, a second intermediate layer IL2, a third metalens layer ML3, and a window member WN.

Compared to FIG. 24, the optical device 11 of FIG. 28 may include the second intermediate layer IL2 instead of the second sub-substrate SSUB2 and the spacer SPC in contact with the lower surface of the second sub-substrate SSUB2.

The second intermediate layer IL2 may be disposed on the first sub-substrate SSUB1. The second intermediate layer IL2 may cover a plurality of second nanostructures NS2 and a second non-refractive portion TS2, and may provide a flat upper surface of the second metalens layer ML2b.

The second intermediate layer IL2 of FIG. 28 may be substantially identical to the second intermediate layer IL2 of the above-described embodiments.

Although the second non-refractive portion TS2 and the third non-refractive portion TS3 are aligned in the thickness direction of the substrate SUB in the example shown in FIG. 28, the embodiments of the present disclosure are not limited thereto. A part of the third non-refractive portion TS3 may not overlap with the second non-refractive portion TS2. In other words, a part of the third non-refractive portion TS3 may overlap with a plurality of second nanostructures NS2. In addition, the width and shape of the third non-refractive portion TS3 may be different from the width and shape of the second non-refractive portion TS2, respectively.

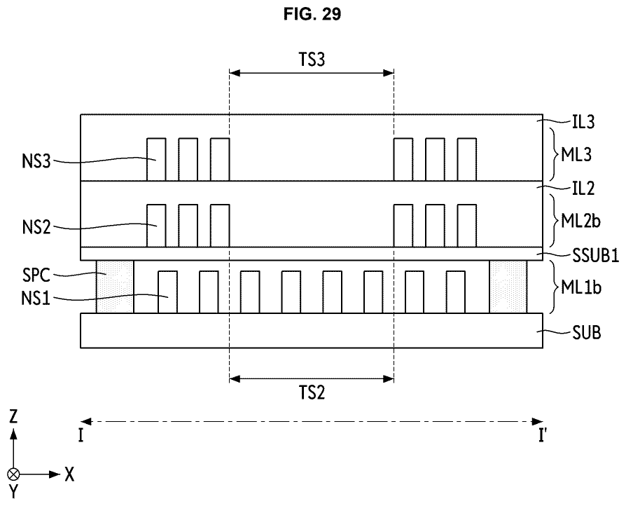

FIG. 29 is a cross-sectional view of the optical device, taken along line I-I′ of FIGS. 9, 10, and 15. The following description will focus on differences and the redundant description will not be provided.

Referring to FIG. 29, an optical device 11 according to some embodiments of the present disclosure may include a substrate SUB, a first metalens layer ML1b, a second metalens layer ML2b, a second intermediate layer IL2, a third metalens layer ML3, and a third intermediate layer IL3.

Compared to FIG. 28, the optical device 11 of FIG. 29 may include the third intermediate layer IL3 instead of the spacer SPC of the window member WN and the third metalens layer ML3.

The third intermediate layer IL3 may be disposed on the second intermediate layer IL2. The third intermediate layer IL3 may cover a plurality of third nanostructures NS3 and a third non-refractive portion TS3, and may provide a flat upper surface of the third metalens layer ML3.

The third intermediate layer IL3 of FIG. 29 may be substantially identical to the third intermediate layer IL3 of the above-described embodiments.

Although the second non-refractive portion TS2 and the third non-refractive portion TS3 are aligned in the thickness direction of the substrate SUB in the example shown in FIG. 29, the embodiments of the present disclosure are not limited thereto. A part of the third non-refractive portion TS3 may not overlap with the second non-refractive portion TS2. In other words, a part of the third non-refractive portion TS3 may overlap with a plurality of second nanostructures NS2. In addition, the width and shape of the third non-refractive portion TS3 may be different from the width and shape of the second non-refractive portion TS2, respectively.

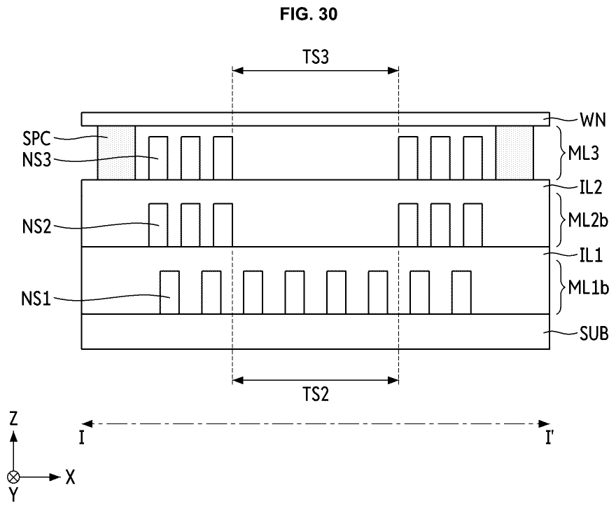

FIG. 30 is a cross-sectional view of the optical device, taken along line I-I′ of FIGS. 9, 10, and 15. The following description will focus on differences and the redundant description will not be provided.

Referring to FIG. 30, an optical device 11 according to some embodiments of the present disclosure may include a substrate SUB, a first metalens layer ML1b, a first intermediate layer IL1, a second metalens layer ML2b, a second intermediate layer IL2, a third metalens layer ML3, and a window member WN.

Compared to FIG. 28, the optical device 11 of FIG. 30 may include the first intermediate layer IL1 instead of the spacer SPC of the first sub-substrate SSUB1 and the first metalens layer ML1a.

The first intermediate layer IL1 may be disposed on the substrate SUB. The first intermediate layer IL1 may cover a plurality of first nanostructures NS1 disposed on the substrate SUB and may provide a flat upper surface of the first metalens layer ML1b.

The first intermediate layer IL1 of FIG. 30 may be substantially identical to the first intermediate layer IL1 of the above-described embodiments.

Although the second non-refractive portion TS2 and the third non-refractive portion TS3 are aligned in the thickness direction of the substrate SUB in the example shown in FIG. 30, the embodiments of the present disclosure are not limited thereto. A part of the third non-refractive portion TS3 may not overlap with the second non-refractive portion TS2. In other words, a part of the third non-refractive portion TS3 may overlap with a plurality of second nanostructures NS2. In addition, the width and shape of the third non-refractive portion TS3 may be different from the width and shape of the second non-refractive portion TS2, respectively.

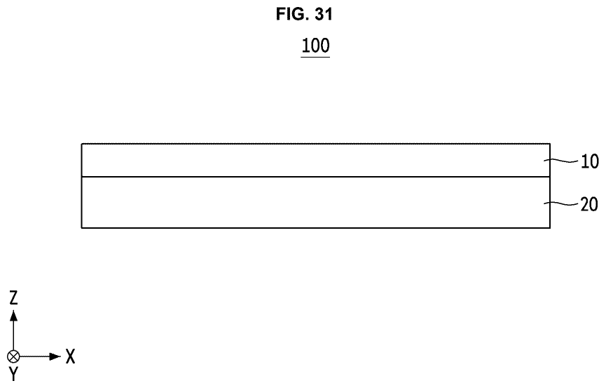

FIG. 31 is a cross-sectional view of the optical device, taken along line I-I′ of FIGS. 9, 10, and 15. The following description will focus on differences and the redundant description will not be provided.

Referring to FIG. 31, an optical device 11 according to some embodiments of the present disclosure may include a substrate SUB, a first metalens layer ML1b, a first intermediate layer IL1, a second metalens layer ML2b, a second intermediate layer IL2, a third metalens layer ML3, and a third intermediate layer IL3.

Compared to FIG. 30, the optical device 11 of FIG. 31 may include the third intermediate layer IL3 instead of the spacer SPC of the window member WN and the third metalens layer ML3.

The third intermediate layer IL3 may be disposed on the second intermediate layer IL2. The third intermediate layer IL3 may cover a plurality of third nanostructures NS3 and a third non-refractive portion TS3 of the third metalens layer ML3, and may provide a flat upper surface of the third metalens layer ML3.

The third intermediate layer IL3 of FIG. 31 may be substantially identical to the third intermediate layer IL3 of the above-described embodiments.

Although the second non-refractive portion TS2 and the third non-refractive portion TS3 are aligned in the thickness direction of the substrate SUB in the example shown in FIG. 31, the embodiments of the present disclosure are not limited thereto. A part of the third non-refractive portion TS3 may not overlap with the second non-refractive portion TS2. In other words, a part of the third non-refractive portion TS3 may overlap with a plurality of second nanostructures NS2. In addition, the width and shape of the third non-refractive portion TS3 may be different from the width and shape of the second non-refractive portion TS2, respectively.

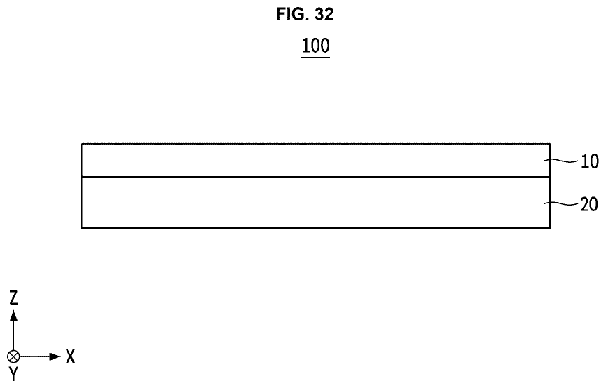

FIG. 32 is a cross-sectional view of a display device including an optical device according to some embodiments of the present disclosure.

Referring to FIG. 32, a display device 100 including an optical device according to some embodiments of the present disclosure may include a display panel 20 and an optical device 10 on a surface of the display panel 20.

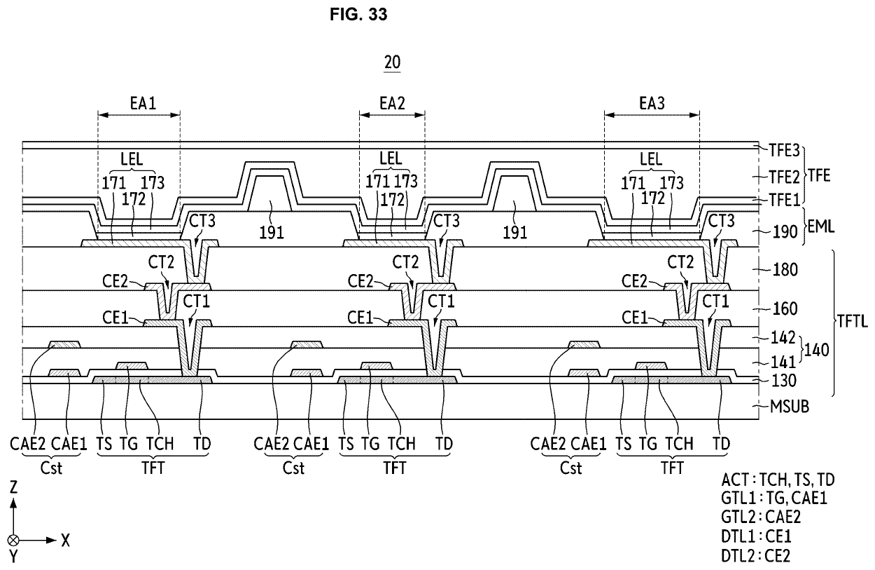

If the display panel 20 has a top-emission architecture where a light-emitting element layer EML (see FIG. 33) emits light in an upward direction (z-axis direction), the optical device 10 may be disposed on the upper surface of the display panel 20.

If the display panel 20 has a bottom-emission architecture where a light-emitting element layer emits light in a downward direction (the opposite direction to the z-axis direction), the optical device 10 may be disposed on the lower surface of the display panel 20.

Although the display panel 20 has the top-emission architecture and the optical device 10 is disposed on the upper surface of the display panel 20 in the example shown in FIG. 32, the embodiments of the present disclosure are not limited thereto.

According to some embodiments of the present disclosure, the optical device 11 may be disposed on the display panel 20.

FIG. 33 is a cross-sectional view of the display panel of FIG. 32.

Referring to FIG. 33, a display layer 20 may include a main substrate SUB, a thin-film transistor layer TFTL, a light-emitting element layer EML, and an encapsulation layer TFE.

The thin-film transistor layer TFTL includes an active layer ACT, a first gate layer GTL1, a second gate layer GTL2, a first data metal layer DTL1, and a second data metal layer DTL2. In addition, the thin-film transistor layer TFTL includes a buffer film BF, a gate insulator 130, a first interlayer dielectric film 141, a second interlayer dielectric film 142, a first planarization film 160, and a second planarization film 180. The thin-film transistor layer TFTL includes a plurality of thin-film transistors TFT. Each of the thin-film transistors includes a channel TCH, a gate electrode TG, a first electrode TS and a second electrode TD.

The active layer ACT may be disposed on the main substrate MSUB. The active layer ACT may include silicon semiconductor such as polycrystalline silicon, monocrystalline silicon and low-temperature polycrystalline silicon, or may include oxide semiconductor.

The active layer ACT may include a channel TCH, a first electrode TS and a second electrode TD of each of the thin-film transistors TFT. The channel TCH may be a region overlapping with the gate electrode TG of the thin-film transistor TFT in the third direction (z-axis direction), which is the thickness direction of the substrate SUB. The first electrode TS may be disposed on one side of the channel TCH, and the second electrode TD may be disposed on the opposite side of the channel TCH. The first electrode TS and the second electrode TD may be regions that do not overlap with the gate electrode TG in the third direction DR3. The first electrode TS and the second electrode TD may be regions having conductivity by doping ions in a silicon semiconductor or an oxide semiconductor.

The gate insulator 130 may be disposed on the active layer ACT. The gate insulator 130 may be formed of an inorganic layer, for example, a silicon nitride layer, a silicon oxynitride layer, a silicon oxide layer, a titanium oxide layer, or an aluminum oxide layer.

The first gate layer GTL1 may be disposed on the gate insulator 130. The first gate layer GTL1 may include the gate electrode TG of each of the thin-film transistors TFT and a first capacitor electrode CAE1. The first gate layer GTL1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first interlayer dielectric film 141 may be disposed over the first gate layer GTL1. The first interlayer dielectric film 141 may be formed of an inorganic layer, for example, a silicon nitride layer, a silicon oxynitride layer, a silicon oxide layer, a titanium oxide layer, or an aluminum oxide layer.

The second gate line GTL2 may be disposed on the first interlayer dielectric film 141. The second gate layer GTL2 may include a second capacitor electrode CAE2. The second capacitor electrode CAE2 may overlap the first capacitor electrode CAE1 in the third direction (z-axis direction). The capacitor Cst may include a first capacitor electrode CAE1 and a second capacitor electrode CAE2. The second gate layer GTL2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second interlayer dielectric film 142 may be disposed over the second gate layer GTL2. The second interlayer dielectric film 142 may be formed of an inorganic layer, for example, a silicon nitride layer, a silicon oxynitride layer, a silicon oxide layer, a titanium oxide layer, or an aluminum oxide layer.

The first data metal layer DTL1 including a first connection electrode CE1 may be disposed on the second interlayer dielectric film 142. The first connection electrode CE1 may be connected to the first electrode TS or the second electrode TD of the thin-film transistor TFT through a first contact hole CT1 penetrating the gate insulator 130, the first interlayer dielectric film 141 and the second interlayer dielectric film 142. The first data metal layer DTL1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The planarization film 160 may be disposed on the first data metal layer DTL to provide a flat surface over the level differences of the active layer ACT, the first gate layer GTL1, the second gate layer GTL2, and the first data metal layer DTL. The first planarization film 160 may be formed of an organic layer such as an acryl resin, an epoxy resin, a phenolic resin, a polyamide resin, and a polyimide resin.

A second data metal layer DTL2 may be disposed on the first planarization film 160. The second data metal layer DTL2 may include a second connection electrode CE2. The second connection electrode CE2 may be connected to the first connection electrode CE1 through a second contact hole CT2 penetrating the first planarization film 160. The second data metal layer DTL2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second planarization film 180 may be disposed on the second data metal layer DTL2. The second planarization film 180 may be formed as an organic layer such as an acryl resin, an epoxy resin, a phenolic resin, a polyamide resin and a polyimide resin.

A light-emitting element layer EML may be disposed on the second planarization film 180. The light-emitting element layer EML may include a plurality of light-emitting elements LEL and a pixel-defining film 190. Each of the light-emitting elements LEL may be, but is not limited to, an organic light-emitting diode including a pixel electrode 171, a light-emitting layer 172 and a common electrode 173.

The pixel electrode 171 may be disposed on the second planarization film 180. The pixel electrode 171 may be connected to the second connection electrode CE2 through a third contact hole CT3 penetrating the second planarization film 180.

In the top-emission structure in which light exits from the light-emitting layer 172 toward the common electrode 173, the pixel electrode 171 may be made of a metal material having a high reflectivity such as a stack structure of aluminum and titanium (Ti/Al/Ti), a stack structure of aluminum and indium tin oxide (ITO) (ITO/Al/ITO), an APC alloy and a stack structure of APC alloy and ITO (ITO/APC/ITO). The APC alloy is an alloy of silver (Ag), palladium (Pd) and copper (Cu).

The pixel-defining layer 190 may be disposed on the second planarization film 180 to cover the edges of each of the pixel electrodes 171 in order to define the light-emitting areas EA. The pixel-defining film 190 may be formed of an organic layer such as an acryl resin, an epoxy resin, a phenolic resin, a polyamide resin and a polyimide resin.

In each of the light-emitting areas EA, the pixel electrode 171, the light-emitting layer 172 and the common electrode 173 are stacked on one another sequentially, so that holes from the pixel electrode 171 and electrons from the common electrode 173 are recombined in the light-emitting layer 172 to emit light.

The light-emitting layer 172 may be disposed on the pixel electrode 171. The light-emitting layer 172 may include an organic material to emit light of a certain color. For example, the light-emitting layer 172 may include a hole transporting layer, an organic material layer, and an electron transporting layer.

The common electrode 173 may be disposed on the light-emitting layer 172. The common electrode 173 may be disposed to cover the light-emitting layer 172. The common electrode 173 may be a common layer formed across the light-emitting areas EA. A capping layer may be formed on the common electrode 173.

In the top-emission organic light-emitting diode, the common electrode 173 may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the common electrode 173 is formed of a semi-transmissive metal material, the light extraction efficiency can be increased by using microcavities.

A spacer 191 may be disposed on the pixel-defining film 190. The spacer 191 may support a mask during a process of fabricating the light-emitting layer 172. The spacer 191 may be formed of an organic layer such as an acryl resin, an epoxy resin, a phenolic resin, a polyamide resin and a polyimide resin.

An encapsulation layer TFE may be disposed on the common electrode 173. The encapsulation layer TFE includes at least one inorganic layer to prevent permeation of oxygen or moisture into the light-emitting element layer EML. In addition, the encapsulation layer TFE includes at least one organic layer to protect the light-emitting element layer EML from foreign substances such as dust. For example, the encapsulation layer TFE may include a first inorganic encapsulation layer TFE1, an organic encapsulation layer TFE2, and a second inorganic encapsulation layer TFE3.

The first inorganic encapsulation film TFE1 may be disposed on the common electrode 173, the organic encapsulation film TFE2 may be disposed on the first inorganic encapsulation film TFE1, and the second inorganic encapsulation film TFE3 may be disposed on the organic encapsulation film TFE2. The first inorganic encapsulation film TFE1 and the second inorganic encapsulation film TFE3 may be made up of multiple layers in which one or more inorganic layers of a silicon nitride layer, a silicon oxynitride layer, a silicon oxide layer, a titanium oxide layer and an aluminum oxide layer are alternately stacked on one another. The organic encapsulation film TFE2 may be an organic film such as an acryl resin, an epoxy resin, a phenolic resin, a polyamide resin, a polyimide resin, etc.

In the example shown in FIG. 33, the third light-emitting area EA3 is larger than the first light-emitting area EA1, and the first light-emitting area EA1 is larger than the second light-emitting area EA2. The first light-emitting area EA1 may be a red light-emitting area, the second light-emitting area EA2 may be a green light-emitting area, and the third light-emitting area EA3 may be a blue light-emitting area. It should be understood, however, that the relative sizes of the light-emitting areas are not limited thereto.

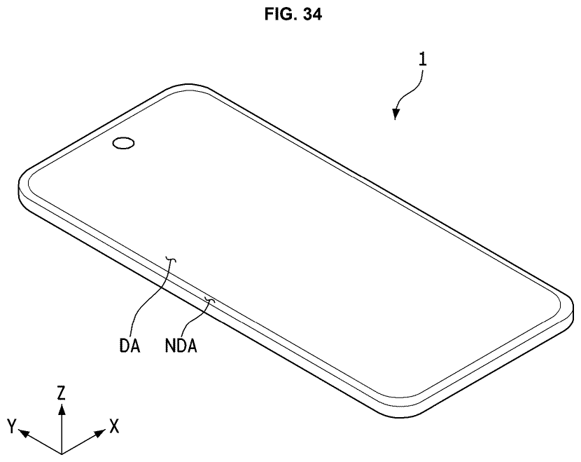

FIG. 34 is a view showing an example of an electronic device including a display device according to some embodiments of the present disclosure.

Referring to FIG. 34, an electronic device 1 including a display device according to some embodiments of the present disclosure may be a portable electronic device such as a mobile phone, a smart phone, a tablet PC, a mobile communications terminal, an electronic notebook, an electronic book, a portable multimedia player (PMP), a navigation device and an ultra mobile PC (UMPC). In some embodiments, the electronic device 1 including the display device according to some embodiments of the present disclosure may include a television, a laptop computer, a monitor, an electronic billboard, or the Internet of Things (IoT). In some embodiments, the electronic device 1 including the display device according to some embodiments of the present disclosure may be a wearable device such as a smart watch, a watch phone, a glasses-type display, and a head-mounted display (HMD) device. In some embodiments, the electronic device 1 including the display device according to some embodiments of the present disclosure may include a center information display (CID) disposed at the instrument cluster, the center fascia or the dashboard of a vehicle, a room mirror display on the behalf of the side mirrors of a vehicle, or a device placed on the back of each of the front seats that is an entertainment system for passengers at the rear seats of a vehicle.

The electronic device 1 including a display device may include a light-emitting display device such as an organic light-emitting display device using organic light-emitting diodes, an inorganic light-emitting display device including an inorganic semiconductor, and a micro light-emitting display device using micro or nano light-emitting diodes (micro LEDs or nano LEDs). In the foregoing description, an organic light-emitting display device is described as an example of the display device. It is, however, to be understood that the present disclosure is not limited thereto.

The electronic device 1 including the display device includes a display area DA for displaying images, and a non-display area NDA around the display area DA. The display area DA includes pixels for displaying images.

Although a smartphone is shown in FIG. 34 as an example of the electronic device 1 including the display device according to some embodiments of the present disclosure, the embodiments of the present disclosure are not limited thereto.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. An optical device comprising:
a substrate;
a first metalens layer disposed on a surface of the substrate and comprising a plurality of first nanostructures; and
a second metalens layer disposed on the surface of the substrate, overlapping with the first metalens layer in a thickness direction of the substrate, and comprising a plurality of second nanostructures,
wherein the first metalens layer comprises:
a first refractive portion where the plurality of first nanostructures is disposed to refract incident light; and
a first non-refractive portion where the plurality of first nanostructures is not disposed, and
wherein the plurality of second nanostructures overlaps with the first refractive portion and the first non-refractive portion in the thickness direction of the substrate.

2. The optical device of claim 1, wherein the first non-refractive portion is located at a center of the first metalens layer, and
the first refractive portion surrounds the first non-refractive portion.

3. The optical device of claim 1, wherein the plurality of first nanostructures has a first width, a first height, and a first spacing.

4. The optical device of claim 3, wherein minimum values of the first width, the first height and the first spacing range from 50 nm to 300 nm.

5. The optical device of claim 1, wherein the plurality of second nanostructures has a second width, a second height, and a second spacing.

6. The optical device of claim 1, further comprising:
an intermediate layer disposed between the first metalens layer and the second metalens layer,
wherein a refractive index of the intermediate layer is lower than a refractive index of the plurality of first nanostructures.

7. The optical device of claim 6, wherein the intermediate layer contains gas.

8. The optical device of claim 6, wherein the intermediate layer comprises at least one organic film.

9. The optical device of claim 6, wherein the intermediate layer comprises at least one inorganic film.

10. The optical device of claim 1, wherein the second metalens layer comprises: a sub-substrate where the plurality of second nanostructures is disposed on a surface of the sub-substrate.

11. The optical device of claim 10, further comprising: a spacer disposed between the substrate and the sub-substrate to maintain a gap between the substrate and the sub-substrate.

12. The optical device of claim 10, wherein a thickness of the sub-substrate is smaller than a thickness of the substrate.

13. The optical device of claim 1, further comprising:
a third metalens layer overlapping with the first metalens layer and the second metalens layer in the thickness direction of the substrate and comprising a plurality of third nanostructures,
wherein the third metalens layer comprises:
a second refractive portion where the plurality of third nanostructures is disposed to refract incident light; and
a second non-refractive portion where the plurality of third nanostructures is not disposed.

14. The optical device of claim 13, wherein the plurality of second nanostructures overlaps with the second refractive portion and the second non-refractive portion in the thickness direction of the substrate.

15. The optical device of claim 14, wherein the second non-refractive portion is located at a center of the third metalens layer, and
the second refractive portion surrounds the second non-refractive portion.

16. The optical device of claim 14, wherein the second non-refractive portion overlaps with the first non-refractive portion in the thickness direction of the substrate.

17. The optical device of claim 14, wherein the second non-refractive portion overlaps with some of the plurality of first nanostructures in the thickness direction of the substrate.

18. The optical device of claim 13, wherein the plurality of third nanostructures has a third width, a third height, and a third spacing.

19. A display device comprising:
a display panel for displaying images; and
an optical device disposed on a surface of the display panel and configured to change a light path of light output from the display panel,
wherein the optical device comprises:
a substrate;
a first metalens layer disposed on a surface of the substrate and comprising a plurality of first nanostructures; and
a second metalens layer disposed on the surface of the substrate, overlapping with the first metalens layer in a thickness direction of the substrate and comprising a plurality of second nanostructures, and
wherein the first metalens layer comprises:
a first refractive portion where the plurality of first nanostructures is disposed to refract incident light; and
a first non-refractive portion where the plurality of first nanostructures is not disposed, and
wherein the plurality of second nanostructures overlaps with the first refractive portion and the first non-refractive portion in the thickness direction of the substrate.

20. An electronic device comprising a display device, the display device comprising:
a display panel for displaying images; and
an optical device disposed on a surface of the display panel and configured to change a light path of light output from the display panel,
wherein the optical device comprises:
a substrate;
a first metalens layer disposed on a surface of the substrate and comprising a plurality of first nanostructures; and
a second metalens layer disposed on the surface of the substrate, overlapping with the first metalens layer in a thickness direction of the substrate and comprising a plurality of second nanostructures, and
wherein the first metalens layer comprises:
a first refractive portion where the plurality of first nanostructures is disposed to refract incident light; and
a first non-refractive portion where the plurality of first nanostructures is not disposed, and
wherein the plurality of second nanostructures overlaps with the first refractive portion and the first non-refractive portion in the thickness direction of the substrate.
